(19) United States
(12) Patent Application Publication
(10) Pub. No.: US 2019/0035788 A1
(43) Pub. Date: Jan. 31, 2019

(54) SEMICONDUCTOR DEVICES AND METHODS OF MANUFACTURING THE SAME

(71) Applicant: SAMSUNG ELECTRONICS CO., LTD, Suwon-si (KR)

(72) Inventors: MUN-HYEON KIM, SEOUL (KR); SOO-HYEON KIM, UIJEONGBU-SI (KR); BYOUNG-HAK HONG, SEOUL (KR); KEUN-HWI CHO, SEOUL (KR); TOSHINORI FUKAI, SUWON-SI (KR); SHIGENOBU MAEDA, SEONGNAM-SI (KR); HIDENOBU FUKUTOME, SEONGNAM-SI (KR)

(21) Appl. No.: 16/152,832

(22) Filed: Oct. 5, 2018

Related U.S. Application Data
(63) Continuation of application No. 15/209,328, filed on Jul. 13, 2016.

(30) Foreign Application Priority Data
Dec. 3, 2015 (KR) 10-2015-0171499

(51) Int. Cl. H01L 27/092; H01L 29/78; H01L 29/06; H01L 21/8238

(52) U.S. Cl. CPC H01L 27/0924; H01L 29/785; H01L 29/7848; H01L 21/823821; H01L 21/823807; H01L 21/823878; H01L 27/092; H01L 29/0649

(57) ABSTRACT

A semiconductor device includes a substrate, a gate structure, a first impurity region, and a second impurity region. The gate structure may cross over a first active region and a second active region of the substrate. The first insulation structure including a first insulation material may be formed on the first active region, and may be spaced apart from opposite sides of the gate structure. The second insulation structure including a second insulation material different from the first insulation material may be formed on the second active region, and may be spaced apart from opposite sides of the gate structure. The first impurity region may be formed at a portion of the first active region between the gate structure and the first insulation structure, and may be doped with p-type impurities. The second impurity region may be formed at a portion of the second active region between the gate structure and the second insulation structure, and may be doped with n-type, impurities. A stress may be applied onto a channel region of a transistor, so that the semiconductor device may have good electrical characteristics.

### CROSS-REFERENCE TO RELATED APPLICATION

This application is a continuation of U.S. application Ser. No. 15/209,328 filed on Jul. 13, 2016, which claims priority under 35 USC § 119 to Korean Patent Application No. 10-2015-0171499, filed on Dec. 3, 2015 in the Korean Intellectual Property Office (KIPO), the contents of which are incorporated by reference herein in their entirety.

### TECHNICAL FIELD

The present invention relates generally to semiconductor devices and methods of manufacturing the same, more particularly, relates to semiconductor devices including transistors and methods of manufacturing the same.

### DISCUSSION OF RELATED ART

In a highly integrated semiconductor device, characteristics of a transistor may be changed by various elements, for example, the size of the active region for forming the transistor, the arrangement between the gate structures and other patterns, the sizes of the gate structure and other patterns, etc. For example, forming one or more layers of stress inducing materials around the transistor may impart or induce stress in the channel region, and then may change the electrical characteristic of the transistor. There is a constant and continuous drive to increase the performance of the transistor in the semiconductor industry. Applying stress to the channel region of the transistor will result in increasing mobility of electrons or holes, which in turn increases device speed and performance.

### SUMMARY

According to an example embodiment of the present invention, there is provided a semiconductor device. The semiconductor device includes a gate structure, a first insulation structure, a second insulation structure, a first impurity region, and a second impurity region on a substrate. The substrate may include a first active region and a second active region. The gate structure may cross over the first active region and the second active region. The first insulation structure may be formed on the first active region. The first insulation structure may be spaced apart from opposite sides of the gate structure, and may include a first insulation material. The second insulation structure may be formed on the second active region. The second insulation structure may be spaced apart from opposite sides of the gate structure, and may include a second insulation material different from the first insulation material. The first impurity region may be formed at a portion of the first active region between the gate structure and the first insulation structure. The first impurity region may be doped with p-type impurities. The second impurity region may be formed at a portion of the second active region between the gate structure and the second insulation structure. The second impurity region may be doped with n-type impurities.

In an example embodiment of the present invention, the first insulation material may include a material for applying a compressive stress, and the second insulation material may include a material for applying a tensile stress.

In an example embodiment of the present invention, the first insulation material may include silicon oxide, and the second insulation material may include silicon nitride.

In an example embodiment of the present invention, the first insulation structure may contact the first active region of the substrate. A portion of the first insulation structure contacting the first active region of the substrate may include the first insulation material.

In an example embodiment of the present invention, the first insulation structure may be formed in a first trench through the first active region of the substrate, and may include a first insulation liner pattern and a first insulation pattern. The first insulation liner pattern may include silicon oxide and may be formed on sidewalls and a bottom of the first trench. The first insulation pattern may be formed on the first insulation liner pattern and may fill the first trench.

In an example embodiment of the present invention, the second insulation structure may contact the second active region of the substrate. A portion of the second insulation structure contacting the second active region of the substrate may include the second insulation material.

In an example embodiment of the present invention, the second insulation structure may be formed in a second trench through the second active region of the substrate, and may include a second insulation liner pattern and a second insulation pattern. The second insulation liner pattern may include silicon nitride, and may be formed on sidewalls and a bottom of the second trench. The second insulation pattern may be formed on the second insulation liner pattern, and may fill the second trench.

In an example embodiment of the present invention, one end portions of the first insulation structure may contact one end portion of the second insulation structure, and the first and second insulation structures may be merged into one insulation structure.

In an example embodiment of the present invention, the first insulation structure may extend in parallel with the gate structure, and may penetrate through the first active region of the substrate. The second insulation structure may extend in parallel with the gate structure, and may penetrate through the second active region of the substrate.

In an example embodiment of the present invention, a lower surface of each of the first and second insulation structures may be lower than a lower surface of the gate structure.

In an example embodiment of the present invention, the gate structure may include a first gate structure on the first active region of the substrate. The first gate structure may include a gate insulation pattern, a first conductive pattern, a second conductive pattern, an electrode pattern and a hard mask sequentially stacked. The first conductive pattern may include a metal having a work function of a p-type transistor.

In an example embodiment of the present invention, the gate structure may include a second gate structure on the second active region of the substrate. The second gate structure may include a gate insulation pattern, a second conductive pattern, an electrode pattern and a hard mask sequentially stacked. The second conductive pattern may include a metal having a work function of an n-type transistor.

In an example embodiment of the present invention, a plurality of active fins may be further formed on the first and second active regions of the substrate. Each of the plurality of active fins may protrude from the substrate, and may extend in a first direction.

In an example embodiment of the present invention, the first insulation structure may have a width substantially the same as a width of the second insulation structure.

In an example embodiment of the present invention, the first insulation structure may have a width different from a width of the second insulation structure.

In an example embodiment of the present invention, a first epitaxial pattern and a second epitaxial pattern may be further formed on the substrate. The first impurity region may be formed in the first epitaxial pattern, and the second impurity region may be formed in the second epitaxial pattern.

According to an example embodiment of the present invention, there is provided a semiconductor device. The semiconductor device includes a plurality of p-type transistors, a plurality of n-type transistors, a first insulation structure and a second insulation structure. Each of the plurality of p-type transistors may be formed on a first active region of a substrate, and may include a first gate structure and a first impurity region. Each of the plurality of n-type transistors may be formed on a second active region of the substrate, and may include a second gate structure and a second impurity region. The first insulation structure may be formed between two adjacent ones from among the plurality of p-type transistors. The first insulation structure may include a first insulation. material for applying a compressive stress. The second insulation structure may be formed between two adjacent ones from among the plurality of n-type transistors. The second insulation structure may include a second insulation material for applying a tensile stress.

In an example embodiment of the present invention, one end portion of the first gate structure may contact one end portion of the second gate structure, and the first and second gate structures may be merged into one gate structure across the first and second active regions.

In an example embodiment, one end portion of the first insulation structure may contact one end portion of the second insulation structure, and the first and second insulation structures may be merged into one insulation structure.

In an example embodiment of the present invention, the first insulation material may include silicon oxide, and the second insulation material may include silicon nitride.

In an example embodiment of the present invention, the first insulation structure may contact the first active region of the substrate. A portion of the first insulation structure contacting the first active region of the substrate may include the first insulation material.

In an example embodiment of the present invention, the second insulation structure may contact the second active region of the substrate. A portion of the second insulation structure contacting the second active region of the substrate may include the second insulation material.

In an example embodiment of the present invention, the first insulation structure may have a width substantially the same as a width of the second insulation structure.

In an example embodiment of the present invention, the first insulation structure may have a width different from a width of the second insulation structure.

According to an example embodiment of the present invention, there is provided a semiconductor device. The semiconductor device includes a plurality of p-type transistors, a plurality of n-type transistors, a first insulation structure and a second insulation structure. The plurality of p-type transistors may be formed on a first active region of a substrate. Each of the plurality of p-type transistors may include a first gate structure and a first impurity region. The plurality of n-type transistors may be formed on a second active region of the substrate. Each of the plurality of n-type transistors may include a second gate structure and a second impurity region. The first insulation structure may be formed through the first active region between two adjacent ones from among the plurality of p-type transistors. The first insulation structure may include a first insulation material. The second insulation structure may be formed through the second active region between two adjacent one from among the plurality of n-type transistors. The second insulation structure may include a second insulation material different from the first insulation material. One end portion of the first insulation structure may contact one end portion of the second insulation structure, and the first and second insulation structures may extend in a direction.

In an example embodiment of the present invention, the first insulation material may include a material for applying a compressive stress, and the second insulation material may include a material for applying a tensile stress.

In an example embodiment of the present invention, the first insulation structure may contact the first active region of the substrate. A portion of the first insulation structure contacting the first active region of the substrate may include the first insulation material,

In an example embodiment of the present invention, the second insulation structure may contact the second active region of the substrate. A portion of the second insulation structure contacting the second active region of the substrate may include the second insulation material.

In an example embodiment of the present invention, the first insulation structure may have a width substantially the same as a width of the second insulation structure.

In an example embodiment of the present invention, the first insulation structure may have a width different from a width of the second insulation structure.

According to an example embodiment of the present invention, there is provided a method of manufacturing a semiconductor device. In the method, a dummy gate structure and a mold structure may be formed on a first active region and a second active region of a substrate. The dummy gate structure and the mold structure may cross over the first and second active regions. A plurality of first impurity regions may be formed at a portion of the first active region of the substrate between the dummy gate structure and the mold structure. The plurality of first impurity regions may be doped with p-type impurities. A plurality of second impurity regions may be formed at a portion of the second active region of the substrate between the dummy gate structure and the mold structure. The plurality of second impurity regions may be doped with n-type impurities. The mold structure on the first active region of the substrate may be replaced with a first insulation structure including a first insulation material. The mold structure on the second active region of the substrate may be replaced with a second insulation structure including a second insulation material which is different from the first insulation material. The dummy gate structure may be replaced with a gate structure.

In an example embodiment of the present invention, when the mold structure on the first active region is replaced with the first insulation structure including the first insulation material, a portion of the mold structure on the first active region of the substrate may be etched to form a first trench, and the first insulation structure including the first insulation material may be formed in the first trench.

In an example embodiment of the present invention, when the mold structure on the second active region is replaced with the second insulation structure including the second insulation material, a portion of the mold structure on the second active region of the substrate may be etched to form a second trench, and the second insulation structure including the second insulation material may be formed in the second trench.

In an example embodiment of the present invention, when the mold structure on the first active region is replaced with the first insulation structure including the first insulation material, a portion of the mold structure on the first active region of the substrate may be etched to form a first trench a first insulation liner pattern including the first insulation material may be farmed on sidewalls and a bottom of the first trench, and a first insulation pattern may be formed on the first insulation liner pattern to fill the first trench to from the first insulation structure.

In an example embodiment of the present invention, when the mold structure on the second active region is replaced with the second insulation structure including the second insulation material, a portion of the mold structure on the second active region of the substrate may be etched to form a second trench, a second insulation liner pattern including the second insulation material may be formed on sidewalls and a bottom of the second trench, a second insulation pattern may be formed on the second insulation liner pattern to fill the second trench to form the second insulation structure.

In an example embodiment of the present invention, the first insulation structure may contact the first active region of the substrate. A portion of the first insulation structure contacting the first active region of the substrate may include the first insulation material.

In an example embodiment of the present invention, the first insulation material may include silicon oxide, and the second insulation material may include silicon nitride,

In an example embodiment of the present invention, when the dummy gate structure is replaced with the gate structure, the dummy gate structure may be etched to form a third trench.

The first gate structure may be formed in the third trench on the first active region of the substrate. The first gate structure may include a gate insulation pattern, a first conductive pattern, a second conductive pattern, an electrode pattern and a hard mask sequentially stacked. The second gate structure may be formed in the third trench on the second active region of the substrate. The second gate structure may include a gate insulation pattern, a second conductive pattern, an electrode pattern and a hard mask sequentially stacked.

According to an example embodiment of the present invention, there is provided a. method of manufacturing a semiconductor device. In the method, a dummy gate structure and a mold structure may be formed on a. first active region and a second active region of a substrate. The dummy gate structure and the mold structure may cross over the first and second active regions. A plurality of first impurity regions may be formed at a portion of the first active region of the substrate between the dummy gate structure and the mold structure. The plurality of first impurity regions may be doped with p-type impurities. A plurality of second impurity regions may be formed at a portion of the second active region of the substrate between the dummy gate structure and the mold structure. The plurality of second impurity regions may be doped with n-type impurities. The mold structure may be removed through etching on the first active region to form a first trench, and on the second active region to form a second trench. An insulation liner pattern including a first insulation material may be formed on sidewalls and bottoms of the first and second trenches. A portion of the insulation liner pattern on the second. active region may be completely removed from the second trench. A second insulation material different from the first insulation material may be deposited on the insulation liner pattern to fill. the first trench to form a first insulation structure on the first active region, and the second insulation material may be deposited to fill the second trench to form a second insulation structure on the second active region. The dummy gate structure may be replaced with a gate structure. The first insulation material may include a material for applying a compressive stress, and the second insulation material may include a material for applying a tensile stress.

In an example embodiment of the present invention, the first insulation material may include silicon oxide, and the second insulation material may include silicon nitride.

According to an example embodiment of the present invention, the semiconductor device may include the transistor having good electrical characteristics. Also, the semiconductor device may have high reliability.

### BRIEF DESCRIPTION OF THE DRAWINGS

Example embodiments of the present invention will be more clearly understood from the following detailed description taken in conjunction with the accompanying drawings, and in which:

FIGS. 1, 2, 3A and 3B are a plan view, a cross-sectional view and perspective views, respectively, illustrating a semiconductor device in accordance with an example embodiment of the present invention;

FIGS. 4A to 14B are plan views and cross-sectional views illustrating stages of a method of manufacturing a semiconductor device in accordance with an example embodiment of the present invention;

FIG. 15 is a cross-sectional. view illustrating the semiconductor device in accordance with an example embodiment of the present invention;

FIGS. 16A and 16B are a plan view and a cross-sectional view, respectively, illustrating stages of a method of manufacturing a semiconductor device in accordance with an example embodiment of the present invention;

FIGS. 17A to 19B are plan views and cross-sectional views illustrating stages of a method of manufacturing a semiconductor device in accordance with an example embodiment of the present invention;

FIG. 20 is a cross-sectional view illustrating the semiconductor device in accordance with an example embodiment of the present invention;

FIGS. 21A and 21B are a plan view and a cross-sectional view, respectively, illustrating stages of a method of manufacturing a semiconductor device in accordance with an example embodiment of the present invention;

FIGS. 22A and 22B are a plan view and a cross-sectional view, respectively, illustrating stages of a method of manufacturing a semiconductor device in accordance with an example embodiment of the present invention;

FIGS. 23A and 23B are a plan view and a cross-sectional view, respectively, illustrating a semiconductor device in accordance with an example embodiment of the present invention; and

FIGS. 24A and 24B are a plan view and a cross-sectional view, respectively, illustrating a semiconductor device in accordance with an example embodiment of the present invention.

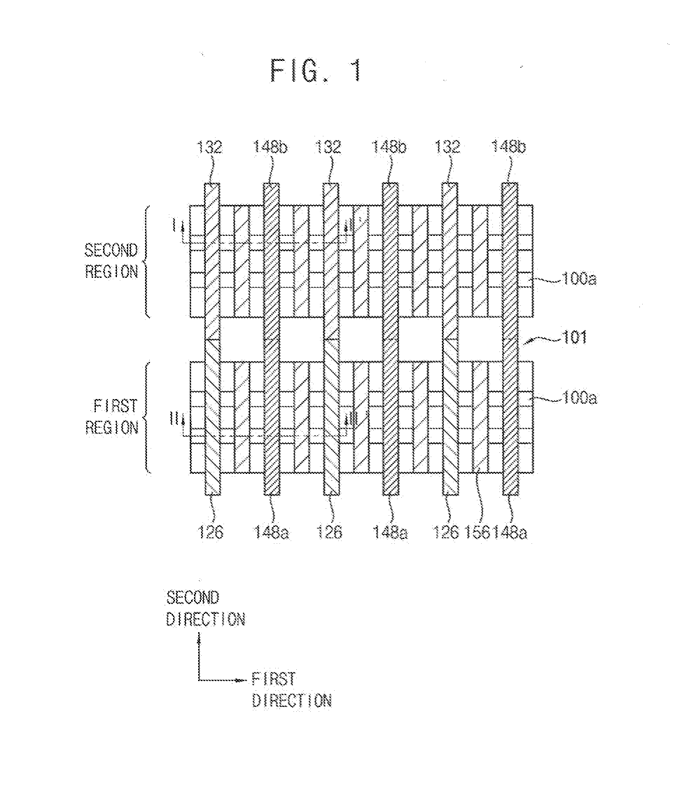

Since the drawings in FIGS. 1-24 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Various example embodiments of the present invention will be described more fully hereinafter with reference to the accompanying drawings, in which some example embodiments are shown. The present inventive concept may, however, be embodied in many different forms and should not be construed as limited to the example embodiments set forth herein, Rather, these example embodiments are provided so that this description will be thorough and complete, and will fully convey the scope of the present inventive concept to those skilled in the art,

It will be understood that when an element or layer is referred to as being “on”, “connected to” or “coupled to” another element or layer, it can be directly on, connected or coupled to the other element or layer, or intervening elements or layers may be present. In contrast, when an element or layer is referred to as being “directly on”, “directly connected to” or “directly coupled to” another element or layer, there are no intervening elements or layers present. Like numerals refer to like elements throughout the specification. As used herein, the term “and/or” includes any and all combinations of one or more of the associated listed items.

It will be understood that, although the terms “first”, “second”, “third”, “fourth” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section, or vise versa, without departing from the teachings of the present inventive concept.

Spatially relative terms, such as “beneath”, “below”, “lower”, “above”, “upper” and the like, may be used herein to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the exemplary term “below” can encompass both an orientation of above and below. The device may be oriented differently (for example, rotated 90 degrees or at other orientations) and the spatially relative descriptors used herein would then be interpreted accordingly.

The terminology used herein is for the purpose of describing particular example embodiments and is not intended to be limiting of the present inventive concept. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, components, and/or groups, but do not preclude the presence or addition of one or more other features, integers, steps, operations, elements, components, and/or groups thereof.

Example embodiments of the present invention are described herein with reference to cross-sectional illustrations that are schematic illustrations of idealized example embodiments. As such, variations from the shapes of the illustrations caused from, for example, various manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shapes of the regions of a device, and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIGS. 1, 2, 3A and 3B are a plan view, a cross-sectional view and perspective views, respectively, illustrating a semiconductor device in accordance with an example embodiment of the present invention.

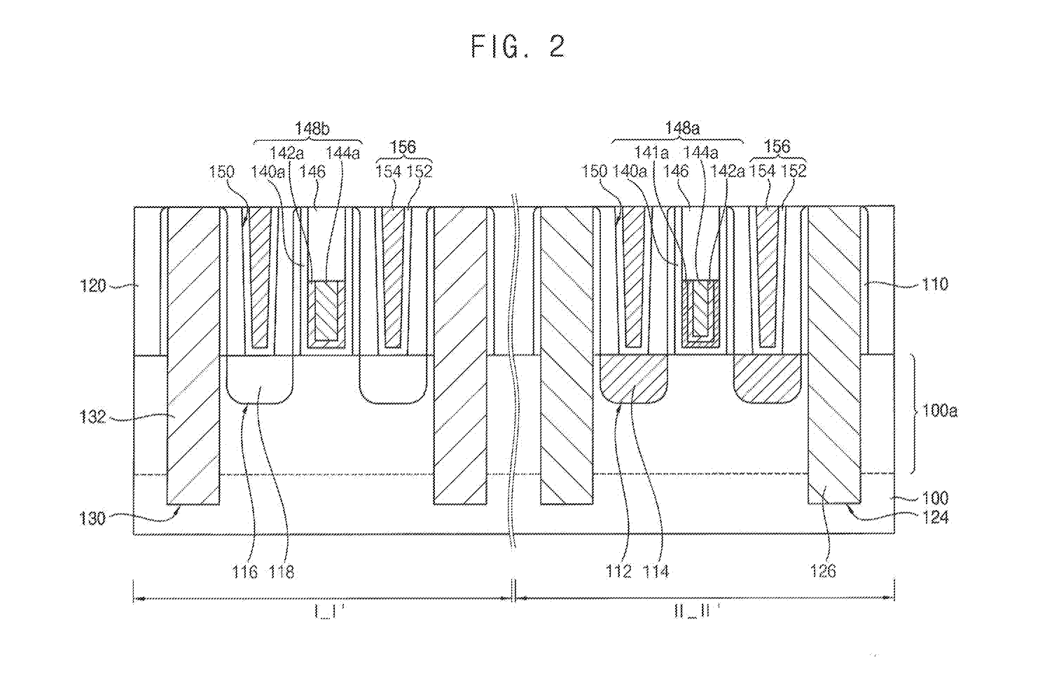

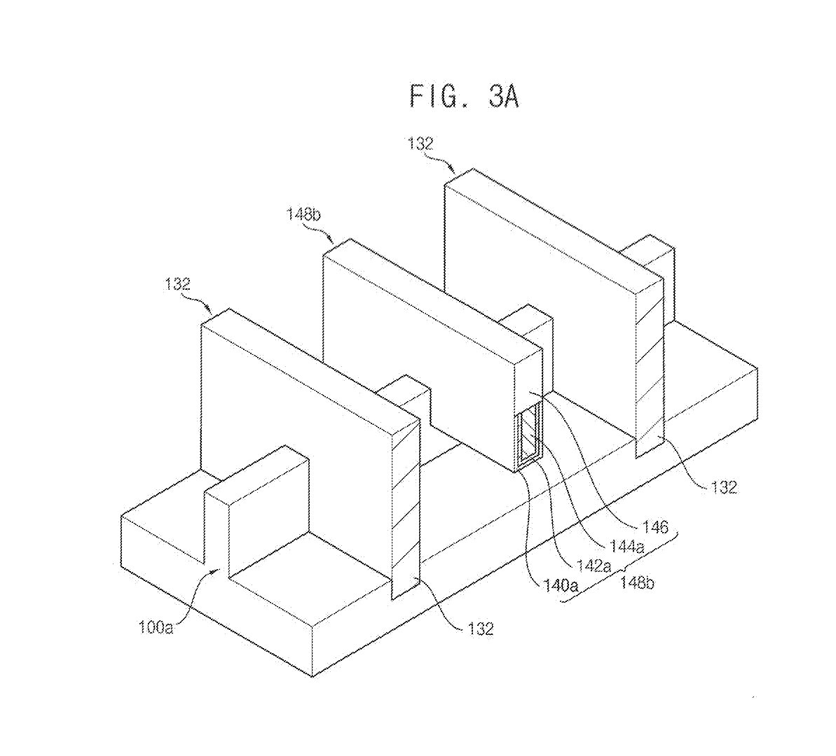

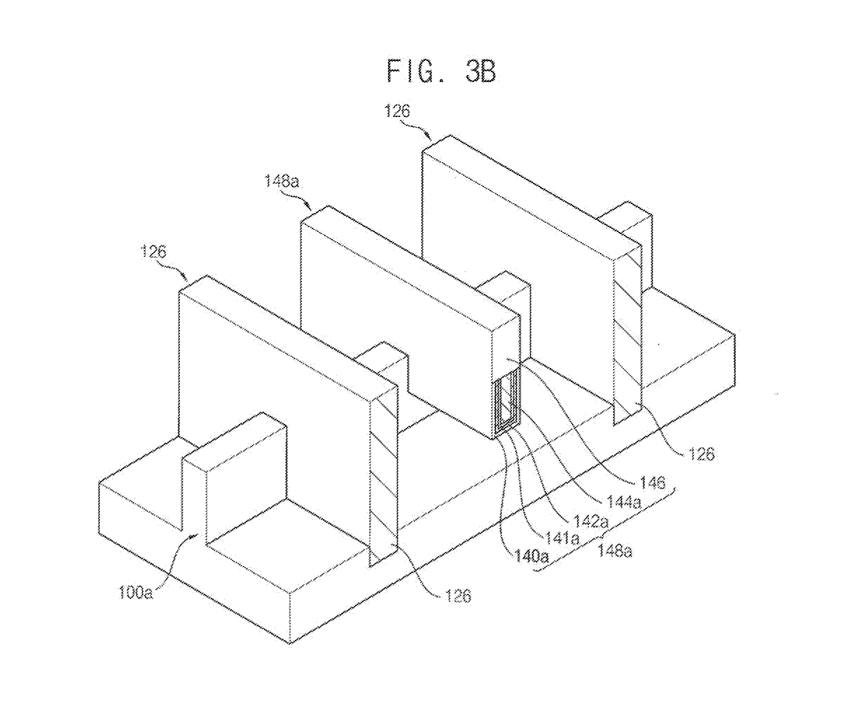

FIG. 2 includes cross-sections taken along lines I-I′ and II-II′ of FIG. 1. FIGS. 3A and 3B show n-type and p-type transistors, respectively, in the semiconductor device. In. FIGS. 3A and 3B, some elements, such as a semiconductor pattern and contact plugs, are omitted.

Referring to 1, 2, 3A and 3B, a substrate 100 may include a first region for forming a p-type transistor and a second region for forming an n-type transistor. A plurality of gate structures, first source/drain regions, second source/drain regions, a first insulation pattern 126 and a second insulation pattern 132 may be formed on the substrate 100. A channel region is between the first source and the first drain regions or between the second source and second drain regions, and is under the gate structure. The first insulation pattern 126 may apply a compressive stress onto the channel region of the p-type transistor, and the second insulation pattern 132 may apply a tensile stress onto the channel region of the n-type transistor.

The substrate 100 may include a semiconductor material, e.g., silicon (Si), germanium (Ge), silicon-germanium (SiGe), etc., or III-V semiconductor compounds, e.g., Gallium phosphide (Ge), Gaallium arsenide (GaAs), Gallium antimonide (GaSb), etc. In an example embodiment of the present invention, the substrate 100 may be a silicon-on-insulator (SOI) substrate, or a germanium-on-insulator (GOI) substrate.

Each of the first and second regions may serve as an active region with the first active region for forming a p-type transistor and the second active region for forming an n-type transistor. An isolation pattern 101 may be formed between the first and second regions, and the isolation pattern 101 may serve as a field region. The isolation pattern 101 may include an oxide, e.g., silica oxide. A plurality of active fins 100a may be formed on the first and second regions. The active tins 100a may protrude upwardly from the substrate 100, and may extend in a first direction. The first and second regions may be spaced apart and separated by the isolation pattern 101 in a second direction perpendicular to the first direction.

Each of the gate structures may extend across the first and second regions. In an example embodiment of the present invention, each of the gate structures may extend in the second direction perpendicular to the first direction.

Each of the gate structures may include first and second gate structures 148a and 148b formed on the first and second regions, respectively. The first and second gate structures 148a and 148b may serve as a gate of the p-type transistor and a gate of the as-type transistor, respectively.

In an example embodiment of the present invention, the first gate structure 148a may include a gate insulation pattern 140a, a first conductive pattern 141a, a second conductive pattern 142a, an electrode pattern 144a and a hard mask 146 sequentially stacked. The gate insulation pattern 140a may include a material having high dielectric constant. In an example embodiment of the present invention, the gate insulation pattern 140a may include a metal oxide, e.g,, hafnium oxide (HfO₂), tantalum oxide (Ta₂O₅), zirconium oxide (Zr₂O₂), etc.

The first conductive pattern 141a may adjust a threshold voltage of the p-type transistor. The first conductive pattern 141a may include a metal or a metal alloy having a work function more than about 4.5 eV for the p-type transistor. In an example embodiment of the present invention, the first conductive pattern 141a may include, e.g., titanium (Ti), titanium nitride (TiN), titanium aluminum nitride (TiAlN), tantalum (Ta), tantalum nitride (TaN), etc. The work function of the first conductive pattern 141a may be controlled by combination of metals included in the first conductive pattern 141a.

The second conductive pattern 142a may adjust a threshold voltage of the n-type transistor, and may be formed on the first conductive pattern 141a.

The electrode pattern 144a may include a metal, e.g., aluminum (Al), copper (Cu), tantalum (Ta), etc., or a metal nitride thereof.

The first and second conductive patterns 141a and 142a and the electrode pattern 144a may serve as a first gate electrode of the p-type transistor. The gate insulation pattern 140a may surround a bottom and sidewalk of the first gate electrode.

The hard mask 146 may be formed on the electrode pattern 144a, and may include nitride, e.g., silicon nitride.

In an example embodiment of the present invention, the second gate structure 148b may include the gate insulation pattern 140a, the second conductive pattern 142a, the electrode pattern 144a and the hard mask 146 sequentially stacked. The second conductive pattern 142a may adjust a threshold voltage of the n-type transistor, and may include a metal or a metal alloy having a work function less than about 4.5 eV fbr the n-type transistor. In an example embodiment of the present invention, the second conductive pattern 142a may include, e.g., titanium (Ti), titanium nitride (TiN), titanium aluminum nitride (TiAlN), tantalum (Ta), tantalum nitride (TaN), etc. The work function of the second conductive pattern 142a may be controlled by combination of metals included in the second conductive pattern 142a.

In an example embodiment of the present invention, the gate insulation pattern 140a, the second conductive pattern 142a, the electrode pattern 144a and the hard mask 146 included in the second gate structure 148b may be substantially the same as the gate insulation pattern 140a, the second conductive pattern 142a, the electrode pattern 144a and the hard mask 146 included in the first gate structure 148a, respectively. That is, the first conductive pattern 141a of the first gate structure 148a may directly contact the gate insulation pattern 140a, and the second conductive pattern 142a of the second gate structure 148b may directly contact the gate insulation pattern 140a. In an example embodiment of the present invention, the first gate structure 148a may have various stacked structure such that the first conductive pattern 141a of the first gate structure 148a may directly contact the gate insulation pattern 140a. The second gate structure 148b may have various stacked structures such that the second conductive pattern 142a of the second gate structure 148b may directly contact the gate insulation pattern 140a. Thus, the stacked structure of each of the first and second gate structures 148a and 148b may not be limited to the above. In an example embodiment of the present invention, each of the first and second gate structures 148a and 148b may include a silicon oxide layer and a doped polysilicon pattern sequentially stacked.

In an example embodiment of the present invention, spacers 110 may be formed on sidewalls of the first and second gate structures 148a and 148b. The spacer 110 may include, e.g., silicon nitride, silicon oxynitride,

A plurality of first recesses 112 may be formed on the active fin 100a adjacent to sidewalls of the first gate structure 148a. A first epitaxial pattern 114 may be formed in each of the plurality of first recesses 112. The first epitaxial pattern 114 may be doped with p-type impurities, e.g., boron (B), aluminum (Al), gallium (Ga), etc., so that the first epitaxial pattern 114 may serve as first source/drain regions of the p-type transistor. Thus, first impurity regions may include the first source/drain regions of the p-type transistor, and may be formed in the first epitaxial patterns 114.

In an example embodiment of the present invention, the first epitaxial pattern 114 may include silicon-germanium. Silicon-germanium included in the first epitaxial pattern 114 may apply a compressive stress onto the channel region of the p-type transistor.

In an example embodiment of the present invention, the first recesses 112 may not be formed on the active fin 100a, and the first epitaxial pattern 114 may not he formed in each of the plurality of first recesses 112. In this case, the p-type impurities may be doped into a surface of the active fin 100a, so that the first source/drain regions of the p-type transistor may be formed at an upper portion of the active fin 100a.

A plurality of second recesses 116 may be formed on the active fin 100a adjacent to sidewalls of the second gate structure 148b. A second epitaxial pattern 118 may be formed in each of the plurality of second recesses 116. The second epitaxial pattern 118 may be doped with n-type impurities, e.g., antimony (Sb), arsenic (As), phosphorous (P), etc., so that the second epitaxial pattern 118 may serve as second source/drain regions of the n-type transistor. In an example embodiment of the present invention, the second epitaxial pattern 118 may include silicon. Thus, second impurity regions may include the second source/drain regions of the n-type transistor, and may be formed in the second epitaxial patterns 118.

In an example embodiment of the present invention, the second recesses 116 may not be formed on the active fin 100a, and the second epitaxial pattern 118 may not be formed in each of the plurality of second recesses 116. In this case, the n-type impurities may be doped into a surface of the active fin 100a, so that the second source/drain regions of the n-type transistor may be formed at an upper portion of the active fin 100a.

In an example embodiment of the present invention, a metal silicide pattern may be formed on each of the first and second epitaxial patterns 114 and 118.

The first insulation pattern 126 may be formed between neighboring ones of a plurality of first gate structures 148a arranged in the first direction, so that a plurality of p-type transistors including the first gate structures 148a may be electrically isolated from each other. The first insulation pattern 126 may be spaced apart from the opposite sides of each of the first gate structures 148a. The first insulation pattern 126 may be positioned between and spaced apart from the two adjacent first gate structures 148a. The first insulation pattern 126 may be formed on the first region. The first insulation pattern 126 may extend in parallel with the first gate structures 148a in the second direction and may penetrate through the first region of the substrate.

The first insulation pattern 126 may serve as a first stressor for applying a compressive stress onto the channel region of the p-type transistor. Thus, the first insulation pattern 126 may include a first insulation material for applying a compressive stress, in an example embodiment of the present invention, the first insulation pattern 126 may include, e.g., silicon oxide. The channel region of the p-type transistor may correspond to a portion of the active fin 100a contacting the first gate structure 148a, and may be doped with n-type impurities. Since the channel region may correspond to a portion of the active fin 100a in the first active region, the portion of the first insulation pattern 126 contacting the first active region of the substrate may include the first insulation material such as, e.g., silicon oxide to apply a compressive stress to the channel region of the p-type transistor. Direct contact may be more efficient in inducing or imparting the stress to the channel region. The first insulation structure may contain just the first insulation material or may contain other material(s) in addition to the first insulation material. For the first insulation structure containing other material(s), the portion contacting the first active region of the substrate may include the first insulation material to apply the compressive stress to the channel region of the p-type transistor, and other portion may contain other material. For example, if a first insulation liner pattern is formed on the bottom and sidewalls of the first insulation pattern 126, the first insulation liner pattern may contact the first active region of the substrate and may include the first insulation material to apply the compressive stress. If the first insulation structure has different materials in different segments vertically stacked in and from the substrate in its structure, the segment or segments contacting the first active region of the substrate may include the first insulation material to apply the compressive stress to the channel region of the p-type transistor, and other segment or segments not contacting the first active region of the substrate may contain other material(s).

In an example embodiment of the present invention, a lower surface of the first insulation pattern 126 may be lower than the lower surface of the active fin 100a. The lower surface of the first insulation pattern 126 may also he lower than the lower surface of the first gate structure 148a. The lower surface may be the bottom surface. The first insulation pattern 126 may extend in a direction substantially perpendicular to an upper surface of the substrate 100. The first insulation pattern 126 may be spaced apart from each of the first source/drain regions. Thus, each of the first source/drain regions may be formed between the first gate structure 148a and the first insulation pattern 126.

In an example embodiment of the present invention, upper surfaces of the first insulation pattern 126 and the first gate structure 148a may be substantially coplanar with each other.

The second insulation pattern 132 may be formed between neighboring ones of a plurality of second gate structures 148b arranged in the first direction, so that a plurality of n-type transistors including the second gate structures 148b may be electrically isolated from each other. The second insulation pattern 132 may be spaced apart from the opposite sides of each. of the second gate structures 148b. The second insulation pattern 132 may be positioned between and spaced apart from two adjacent second gate structures 148b. The second insulation pattern 132 may be formed on the second region. The second insulation pattern 132 may extend in parallel with the second gate structures 148b in the second direction and may penetrate through the second region of the substrate.

The second insulation pattern 132 may serve as a second stressor for applying a tensile stress to the channel region of the n-type transistor. Thus, the second insulation pattern 132 may include a second insulation material for applying a tensile stress. In an example embodiment of the present invention, the second insulation pattern 132 may include, e.g., silicon nitride, silicon oxynitride, etc. The channel region of the n-type transistor may correspond to a portion of the active fin 100a contacting the second gate structure 148b, and may be doped with p-type impurities. Since the channel region may correspond to a portion of the active fin 100a in the second active region, the portion of the second insulation pattern 132 contacting the second active region of the substrate may include the second insulation material such as, e.g., silicon nitride, silicon oxynitride, etc. to apply a tensile stress to the channel region of the n-type transistor.

In an example embodiment of the present invention, a lower surface of the second insulation pattern 132 may be lower than the lower surface of the active fin 100a. The lower surface of the second insulation pattern 132 may also be lower than the lower surface of the second gate structure 148b. The second insulation pattern 132 may extend in a direction substantially perpendicular to the upper surface of the substrate 100. The second insulation pattern 132 may be spaced apart from each of the second source/drain regions. Thus, each of the second source/drain regions may be formed between the second gate structure 148b and the first insulation pattern 132.

In an example embodiment of the present invention, upper surfaces of the second insulation pattern 132 and the second gate structure 148b may be substantially coplanar with each other.

In an example embodiment of the present invention, each of the first gate structure 148a, the second gate structure 148b, the first insulation pattern 126 and the second insulation pattern 132 may have substantially the same width in the first direction, and the width is referred to as a first width.

As a result of the structure described above, the compressive stress may be applied to the channel region of the p-type transistor by the first insulation pattern 126, so that the hole mobility of the p-type transistor may increase. The tensile stress may be applied to the channel region of the n-type transistor by the second insulation pattern 132, so that the electron mobility of the n-type transistor may increase. Thus, a complementary metal-oxide semiconductor (CMOS) transistor including the n-type transistor and the p-type transistor may have enhanced electrical characteristics.

A contact plug 156 may be formed on each of the first source/drain regions and the second source/drain regions. In an example embodiment of the present invention, the contact plug 156 may include a barrier pattern 152 and a metal pattern 154.

As described above, the first insulation pattern 126 may be formed adjacent to both sides in the first direction of the p-type, transistor, and the second insulation pattern 132 may be formed adjacent to both sides in the first direction of the n-type transistor. The first insulation pattern 126 may include a material different from a material of the second insulation pattern 132. Thus, each of the n-type transistor and the p-type transistor may have enhanced electrical characteristics.

In an example embodiment of the present invention, the p-type transistor and the n-type transistor may be fin field effect transistors (FinFETs). However, in an example embodiment of the present invention, the p-type transistor and the n-type transistor may be other types of transistors including the first and second insulation patterns 126 and 132, respectively. For example, the first and second insulation patterns 126 and 132 may be included in a planar transistor or a recessed channel transistor. Also, the first and second insulation patterns 126 and 132 may be included in a transistor formed on a nanowire or a nanobelt. That is, the p-type transistors may be electrically isolated from each other by the first insulation pattern 126, which may include the first material for applying a compressive stress. The n-type transistors may be electrically isolated from each other by the second insulation pattern 132, which may include the second material for applying a tensile stress.

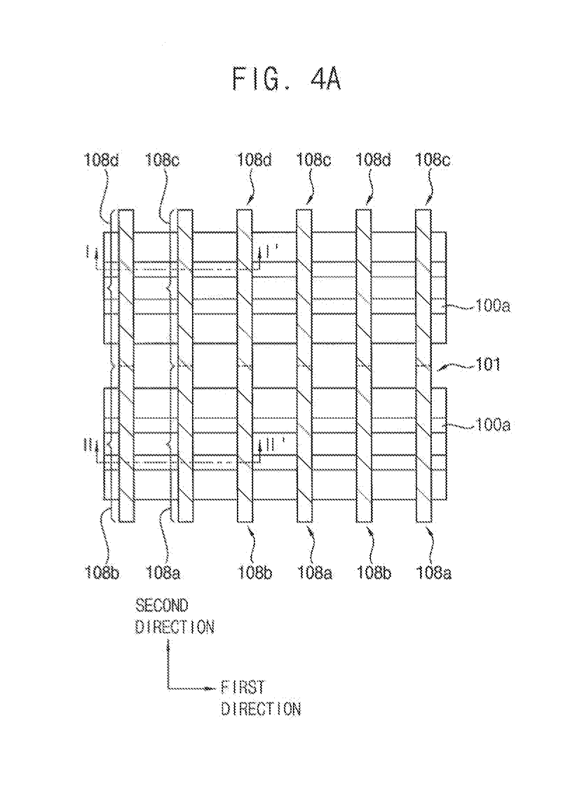

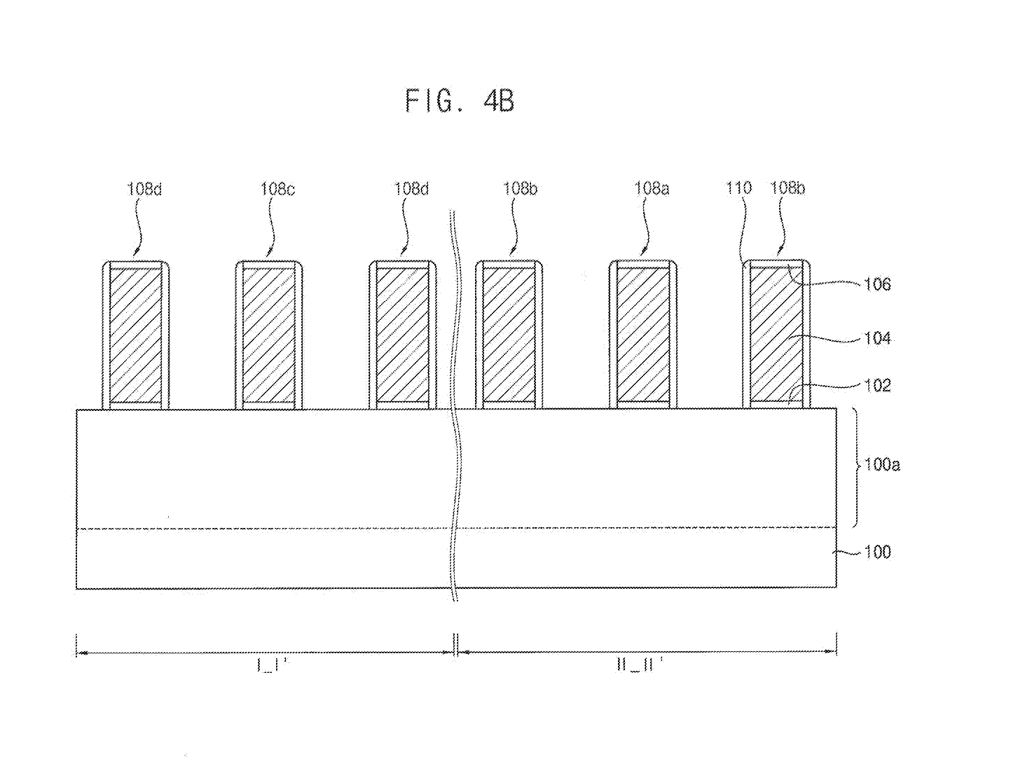

FIGS. 4A to 14B are plan views and cross-sectional views illustrating stages of a method of manufacturing a semiconductor device in accordance with an example embodiment of the present invention. Particularly. FIGS. 4A, 5A, 6A, 7A, 8A, 9A, 10A, 11A, 12A, 13A and 14A are plan views, and FIGS. 4B, 5B, 6B, 7B, 8B, 9B, 10B, 11B, 12B, 13B and 14B are cross-sectional views. FIGS. 4B, 5B, 6B, 7B, 8B, 9B, 10B, 11B, 12B, 13B and 14B are cross-sectional views taken along lines I-I′ and II-II′ of the corresponding plan views. FIGS. 4A, 5A, 6A, 7A, 8A, 9A, 10A, 11A, 12A, 13A and 14A, respectively.

Referring to FIGS. 4A and 4B, an isolation pattern 101 may be formed on a substrate 100 by, e.g., a shallow trench isolation (STI) process. A portion of the substrate 100 between the isolation patterns 101 may serve as an active region. The active region may include a first active region for forming a p-type transistor and a second active region for forming an n-type transistor.

In an example embodiment of the present invention, n-type impurities may be doped into the first region, so that an n-well may be formed at an upper portion of the first region. Also, p-type impurities may be doped into the second region, so that a p-well may be formed at an upper portion of the second region. The first and second regions may extend in a first direction, and may be arranged in parallel to each other,

The substrate 100 may be partially etched to form a plurality of active fins 100a in each of the first and second regions. The active fins 100a may extend in the first direction.

Dummy gate structures 108a and 108c and mold structures 108b and 108d may be formed on the substrate 100, and each of the dummy gate structures 108a and 108c and the mold structures 108b and 108d may extend in a. second direction substantially perpendicular to the first direction to cross the first and second regions.

The dummy gate structures 108a and 108c and the mold structures 108b and 108d may be formed by sequentially forming a. first insulation layer, a first electrode layer and a hard mask layer on the substrate 100, patterning the hard mask layer by a photolithograph process using a photoresist pattern as an etching mask to form a first hard mask 106, and sequentially etching the first electrode layer and the first insulation layer using the first hard mask 106 as an etching mask. Thus, each of the dummy gate structures 108a and 108c and the mold structures 108b and 108d may include a dummy insulation pattern 102, a first electrode 104 and the first hard mask 106 sequentially stacked.

The dummy gate insulation pattern 102 may be formed of an oxide, e.g., silicon oxide. The first electrode 104 may be formed of, e.g., polysilicon. The first hard mask 106 may be formed of a nitride, e.g., silicon nitride.

The first insulation layer may be formed by, e.g., a chemical vapor deposition (CVD) process, an atomic layer deposition (ALD) process, or the like. Alternatively, the first insulation layer may be formed by a thermal oxidation process on an upper portion of the substrate 100. The electrode layer and the first hard mask layer may be formed by, e.g,, a CVD process, an ALD process, etc.

A spacer layer may be formed on the dummy gate structures 108a and 108c, the mold structures 108b and 108d, the active fin 100a, and the isolation pattern 101. The spacer layer may be formed of a nitride, e.g., silicon nitride. In an example embodiment of the present invention, the spacer layer may be formed by, e.g., a CVD process, an ALD process, etc. The spacer layer may be anisotropically etched. to form a spacer 110 on each of sidewalls of the dummy gate structures 108a and 108c and the mold structures 108b and 108d.

In an example embodiment of the present invention, the dummy gate structures 108a and 108c may include a first dummy gate structure 108a. and a second dummy gate structure 108c. The first dummy gate structure 108a may be replaced with a gate structure of the p-type transistor by subsequent processes, and thus the first dummy gate structure 108a may be formed on the first region and with the isolation pattern 101 adjacent to the first region. The second dummy gate structure 108c may be replaced with a gate structure of the n-type transistor by subsequent processes, and thus the second dummy gate structure 108c may be formed on the second region and with the isolation pattern 101 adjacent to the second region. The first and second dummy gate structures 108a and 108c may contact each other on a portion of the isolation pattern 101, and thus may be merged with each other. The dummy gate structure including the first and second dummy gate structures 108a and 108c may extend in the second direction.

The mold structure 108b and 108d may include a first mold structure 108b and a second mold structure 108d. The first mold structure 108b may be replaced with a first insulation pattern by subsequent processes, and the first insulation pattern may electrically isolate the p-type transistors from each other. The second mold structure 108b may be replaced with a second insulation pattern by subsequent processes, and the second insulation pattern may electrically isolate the n-type transistors from each other. The first and second mold structures 108b and 108d may contact each other on a portion of the isolation pattern 101, and thus may be merged with each other. The mold structure including the first and second mold structures 108b and 108d may extend in the second direction, Since the first mold structure 108b may be replaced with the first insulation pattern and the second mold structure 108b may be replaced with the second insulation pattern by subsequent processes, one end portion of the first insulation pattern may contact one end portion of the second insulation pattern on a portion of the isolation pattern 101, and thus the first insulation pattern and the second insulation pattern may be merged with each other into one insulation structure.

In an example embodiment of the present invention, a plurality of dummy gate structures 108a and 108c and a plurality of mold structures 108b and 108d may be alternately formed in the first direction, and may be spaced apart from each other. In an example embodiment of the present invention, a first width in the first direction of each of the dummy gate structures 108a and 108c may be substantially equal to a first width in the first direction of each of the mold structures 108b and 108d. In an example embodiment of the present invention, distances in the first direction between neighboring ones of the dummy gate structures 108a and 108c and the mold structures 108b and 108d may be substantially the same to each other.

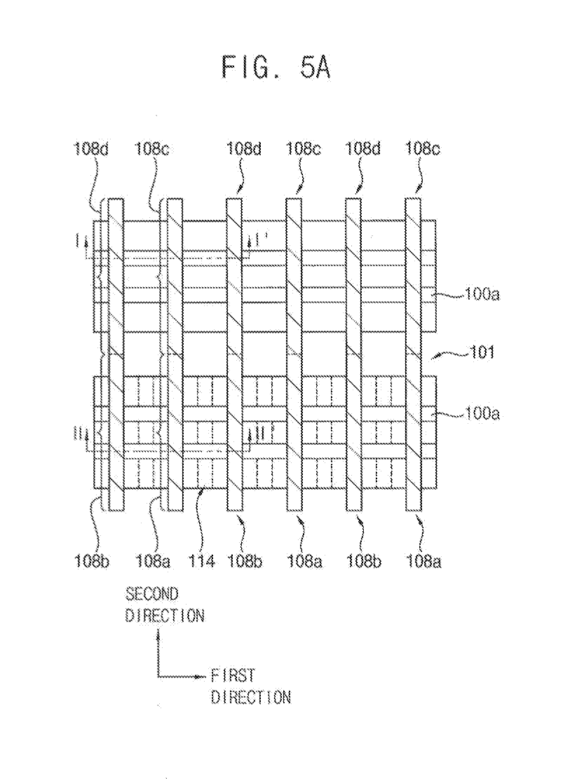

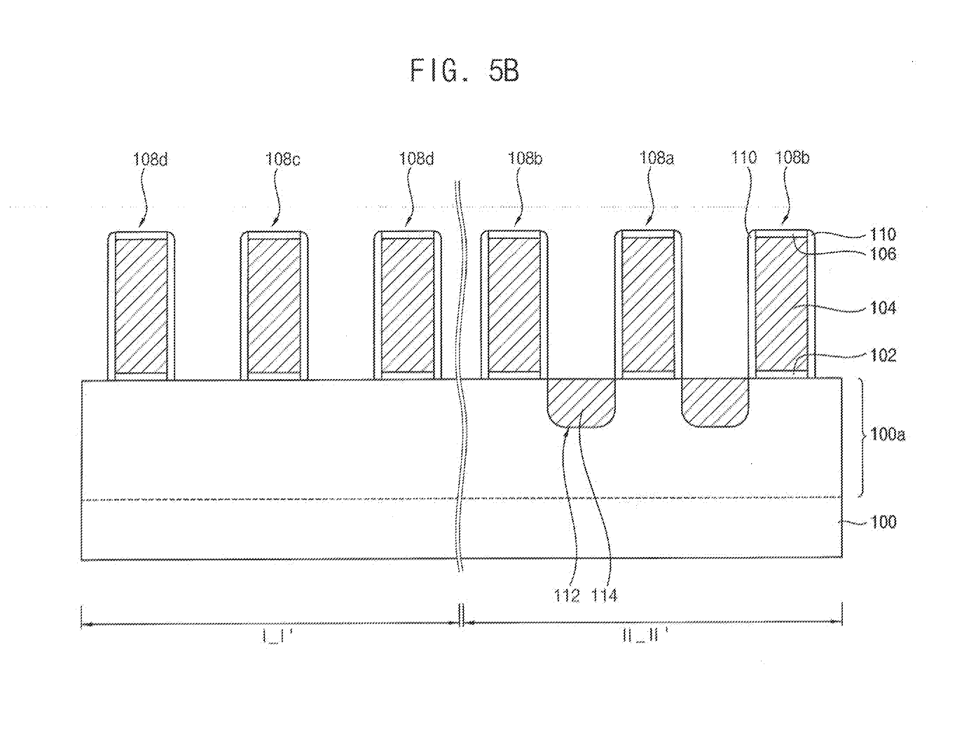

Referring to FIGS. 5A and 5B, a first recess 112 may be formed at an upper portion of the active fin 100a between the first dummy gate structure 108a and the first mold structure 108b on the first region. A first epitaxial pattern 114 including first source/drain regions may be formed to fill the first recess 112.

A first etching mask may be formed on the substrate 100 in the second region to cover the second dummy gate structure 108c and the second mold structure 108d. The upper portion of the active fin 100a between the first dummy gate structure 108a and the first mold structure 108b may be anisotropically etched using the first etching mask to form the first recess 112.

The first epitaxial pattern 114 may be formed to fill the first recess 112. In an example embodiment of the present invention, a plurality of first epitaxial patterns 114 may be arranged in the first direction, and neighboring ones of the first epitaxial patterns 11.4 disposed in the second direction may be connected to each other to be merged into a single layer pattern.

A selective epitaxial growth (SEG) process may be performed using a surface portion of the active fin 100a exposed by the first recess 112 as a seed to form the first epitaxial pattern 114. In an example embodiment of the present invention, the first epitaxial pattern 114 may be formed of silicon-germanium.

In an example embodiment of the present invention, when the SEG process is performed, p-type impurities may be doped in-situ into the first epitaxial pattern 114. Thus, the first epitaxial pattern 114 may serve as the first source/drain regions of the p-type transistor,

In an example embodiment of the present invention, after forming the first epitaxial pattern 114, p-type impurities may be further implanted into the active fin 100a, and the substrate 100 may be annealed.

In an example embodiment of the present invention, the first recess 112 and the first epitaxial pattern 114 may not be formed. In this case, the p-type impurities may be implanted into an upper portion of the active fin 100a between the first dummy gate structure 108a and the first mold structure 108b to form the first source/drain regions of the p-type transistor.

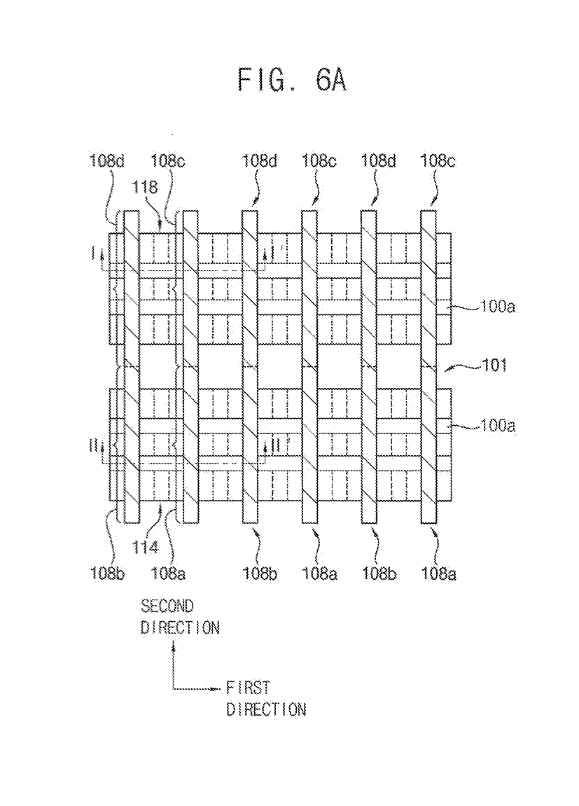

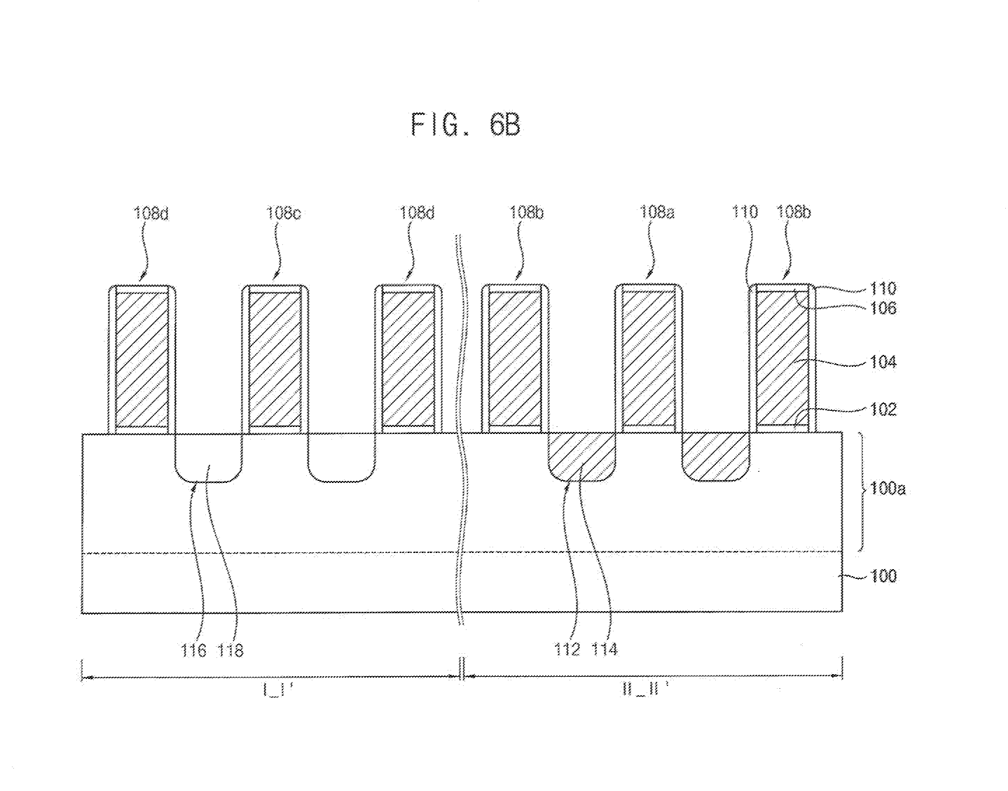

Referring to FIGS. 6A and 6B, a second recess 116 may be formed at an upper portion of the active fin 100a between the second dummy gate structure 108c and the second mold structure 108d in the second region. A second epitaxial pattern 118 including second source/drain regions may be formed to fill the second recess 116.

A second etching mask may be formed on the substrate 100 in the first region to cover the first dummy gate structure 108a and the first mold structure 108b. The upper portion of the active fin 100a between the second dummy gate structure 108c and the second mold structure 108d may be anisotropically etched using the second etching mask to form the second recess 116.

The second epitaxial pattern 118 rna.y be formed to fill the second recess 116. Particularly, a selective epitaxial growth (SEG) process may be performed using a surface portion of the active fin 100a exposed by the second recess 116 as a seed to form the second epitaxial pattern 118. In an example embodiment of the present invention, the second epitaxial pattern 118 may be formed of silicon,

In an example embodiment of the present invention, when the SEG process is performed, n-type impurities may be doped in-situ into the second epitaxial pattern 118. Thus, the second epitaxial pattern 118 may serve as the second source/drain regions of the n-type transistor,

In an example embodiment of the present invention, after forming the second epitaxial pattern 118, n-type impurities may be fin-ther implanted into the active fin 100a, and the substrate 100 may be annealed.

In an example embodiment of the present invention, the second recess 116 and the second epitaxial pattern 118 may not be foiined. In this case, the n-type impurities may be implanted into an upper portion of the active fin 100a between the second dummy gate structure 108c and the second mold structure 108d to form second source/drain regions of the n-type transistor.

In an example embodiment of the present invention, the order of the process for forming the first epitaxial pattern 114 and the process for forming the second epitaxial pattern 118 may be changed. That is, after forming the second epitaxial pattern 118, the first epitaxial pattern 114 may be formed. in an example embodiment of the present invention, only one of the process for forming the first epitaxial pattern 114 and the process for forming the second epitaxial pattern 118 may be performed.

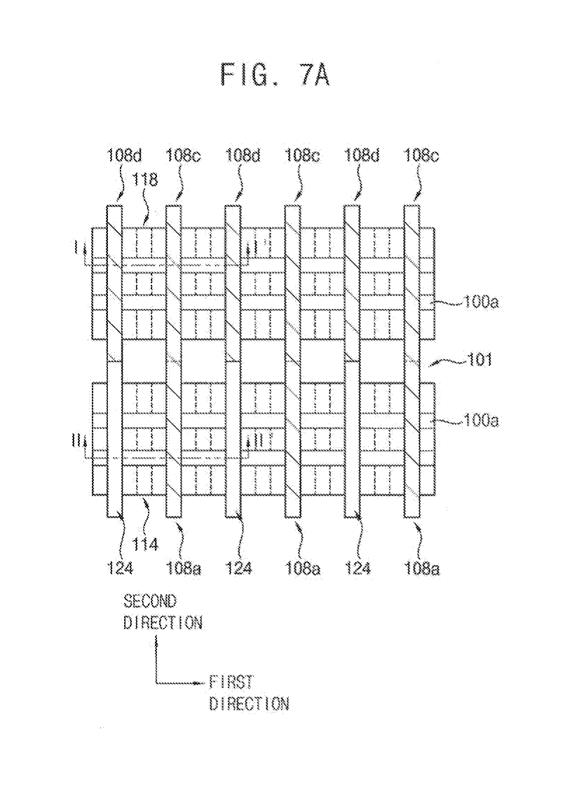

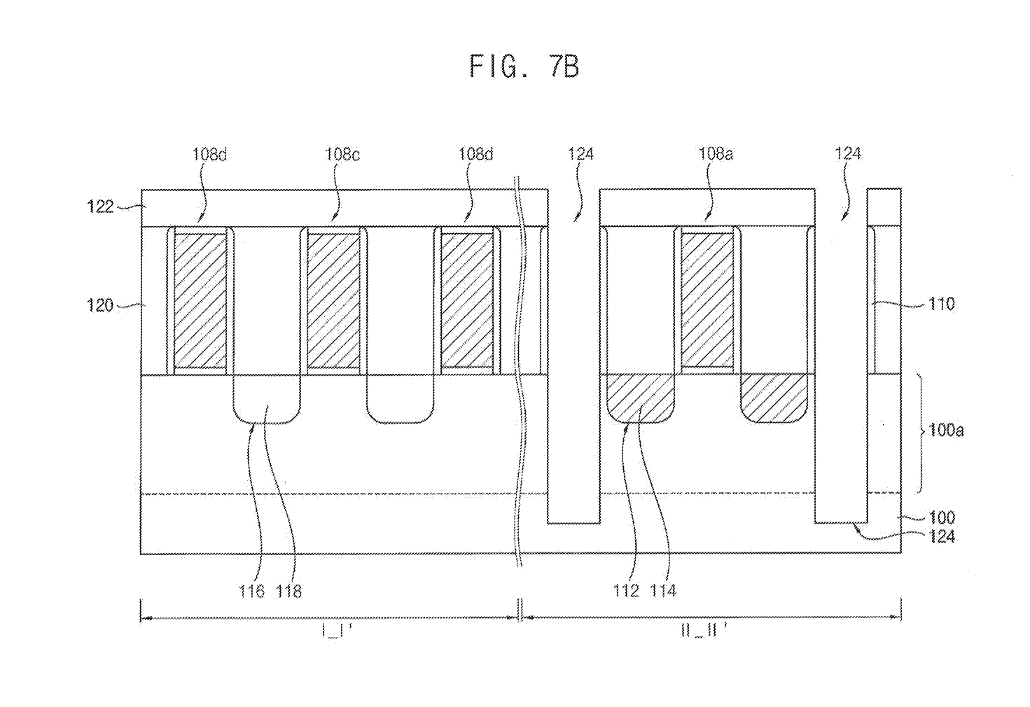

Referring to FIGS. 7A and 7B, an insulating interlayer 120 covering the dummy gate structures 108a and 108c, the mold structures 108b and 108d, the first and second epitaxial patterns 114 and 118 and the isolation pattern 101 may be formed on the substrate 100.

The insulating interlayer 120 may be formed by forming an insulation layer covering the durnm.y gate structures 108a and 108c, the mold structures 108b and 108d, the first and second epitaxial patterns 114 and 118 and the isolation pattern 101, and planarizin.g the insulation layer until upper surfaces of the dummy gate structures 108a and 108c and the mold structures 108b and 108d are exposed. In an example embodiment of the present invention, the planarization process may be performed with a chemical mechanical polishing/Planarization (CMP) process and/or an etch back process.

A third etching mask 122 may be formed to expose only an upper surface of the first mold structure 108b. The first mold structure 108b and the substrate 100 under the first mold structure 108b may be sequentially etched using the third etching mask 122 to form a first trench 124. A bottom of the first trench 124 may be lower than an upper surface of the substrate 100 between the active fins 100a. That is, the bottom of the first trench 124 may be lower than the bottom of the active fin 100a.

The third etching mask 122 may then be removed. Thus, the first dummy gate structure 108a may remain on the first region, and the second dummy gate structure 108c and the second mold structure 108d may remain on the second region.

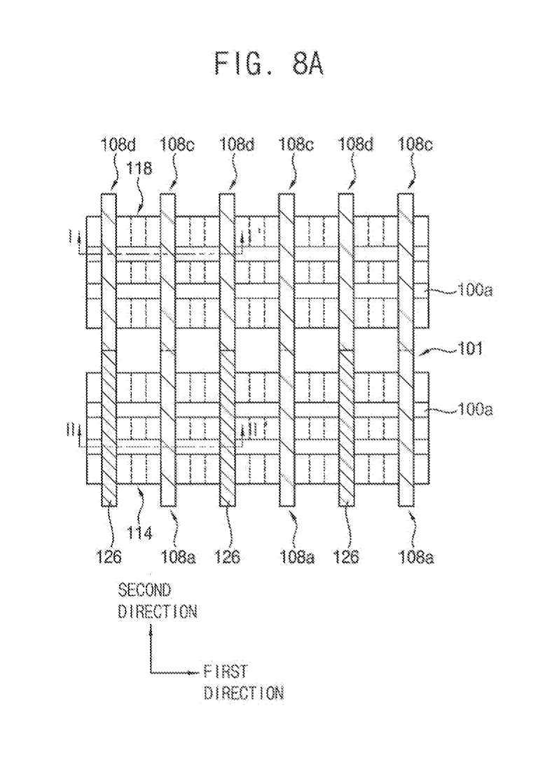

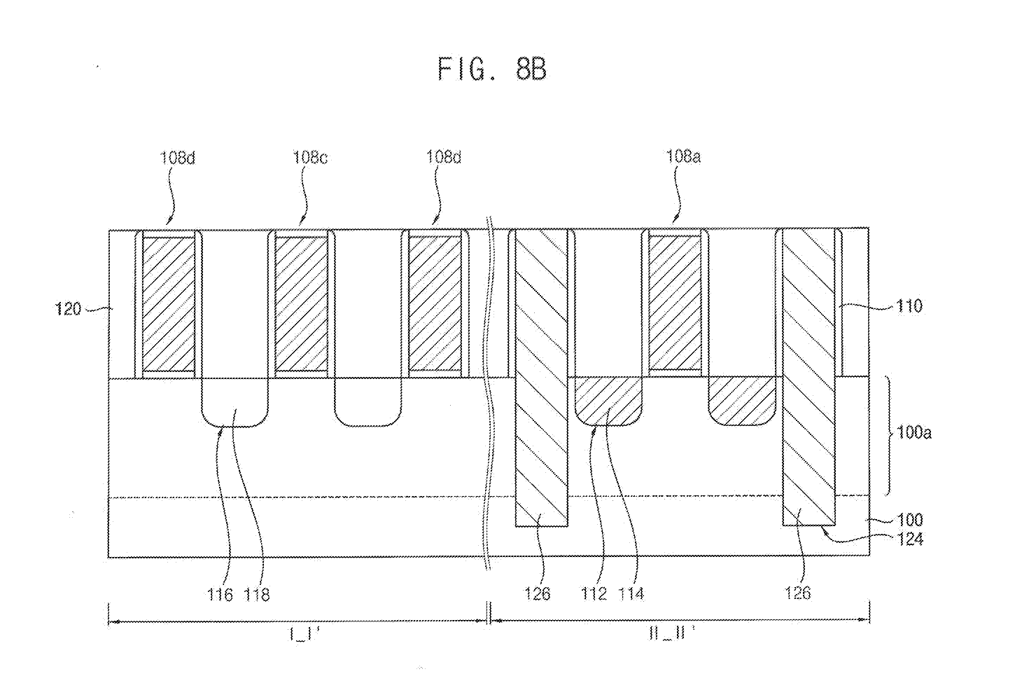

Referring to FIGS. 8A and 8B, a first insulation pattern 126 may be formed to fill the first trench 124. Particularly, a first insulation layer including a first insulation material may be formed to fill the first trench 124. The first insulation material may apply a compressive stress. In an example embodiment of the present invention, the first insulation material may include silicon oxide. In an example embodiment of the present invention, the first insulation layer may be formed by, e.g., a CVD process, a spin coating process, an ALD process, etc. In an example embodiment of the present invention, the first insulation material may include metal oxide or mixture of metal oxides. Combination of various metal oxides may alter the stress and may obtain high compressive stress values.

The first insulation layer may be planarized until. upper surfaces of the first dummy gate structure 108a, the second dummy gate structure 108c and the second mold structure 108d are exposed to form the first insulation pattern 126 in the first trench 124.

The first insulation pattern 126 may apply a compressive stress onto a channel region of the p-type transistor. The channel region may be a portion of the substrate 100 under the first dummy gate structure 108a. Also, a plurality of p-type transistors may be electrically isolated from each other by the first insulation pattern 126.

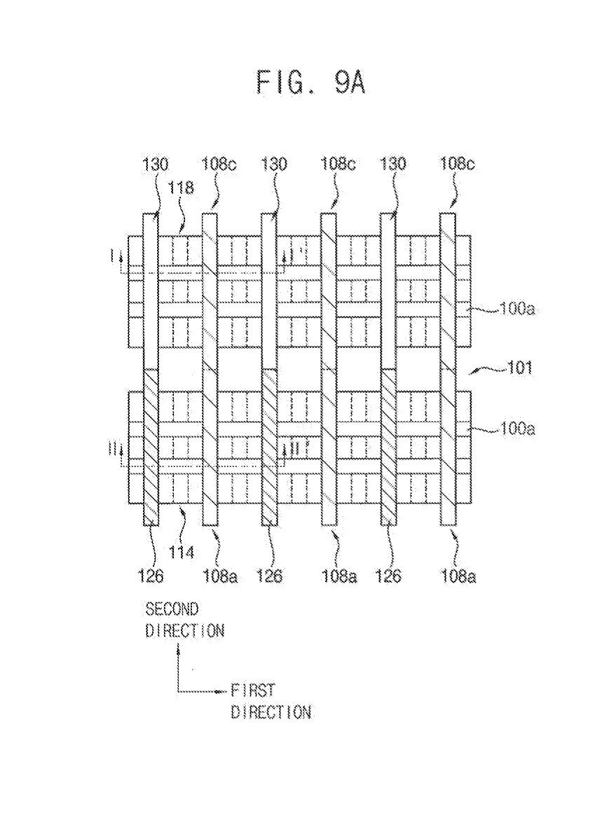

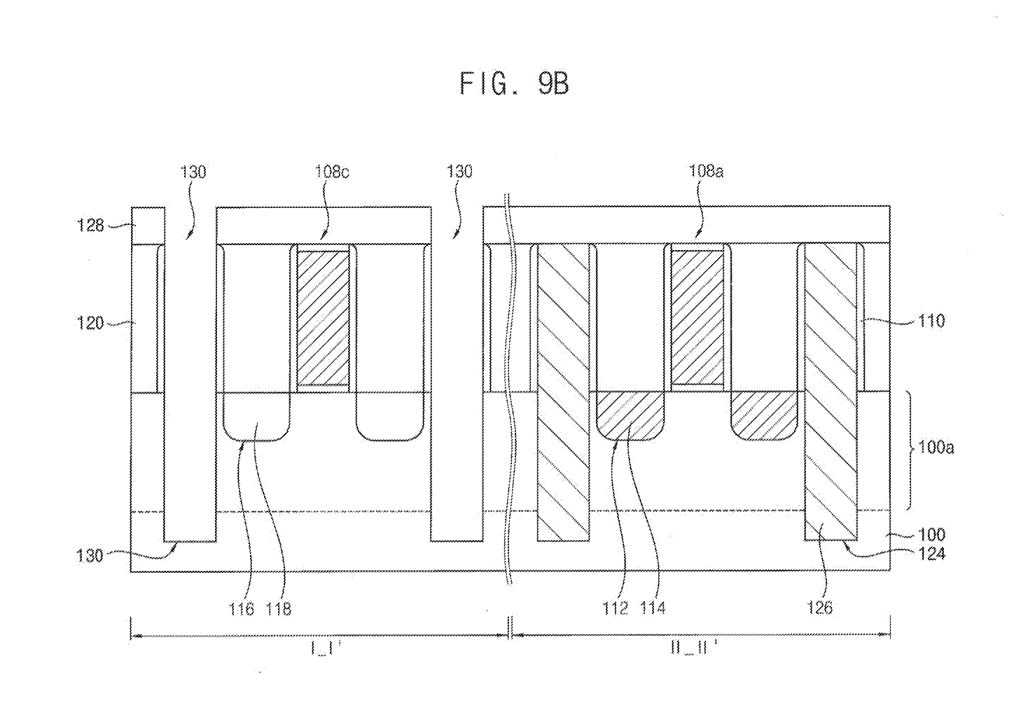

Referring to FIGS. 9A and 9B, a fourth etching mask 128 may be formed to expose only an upper surface of the second mold structure 108d. The second mold structure 108d and the substrate 100 under the second mold structure 108d may be sequentially etched using the fourth etching mask 128 to form a second trench 130. A bottom of the second trench 130 may be lower than the upper surface of the substrate 100 between the active fins 100a. That is, the bottom of the second trench 130 may be lower than the bottom of the active fin 100a.

The fourth etching mask 128 may then be removed. Thus, the first and second dummy gate structures 108a and 108c may remain on the first and second regions, respectively.

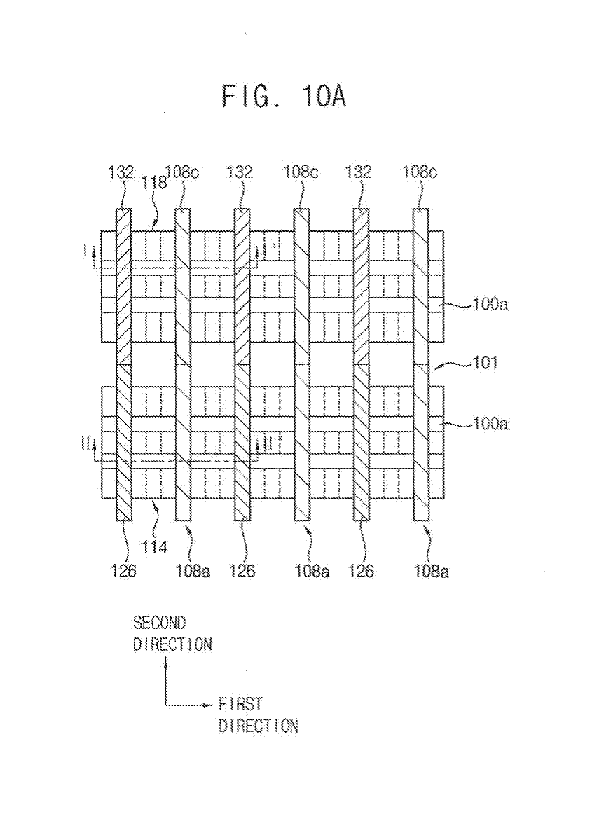

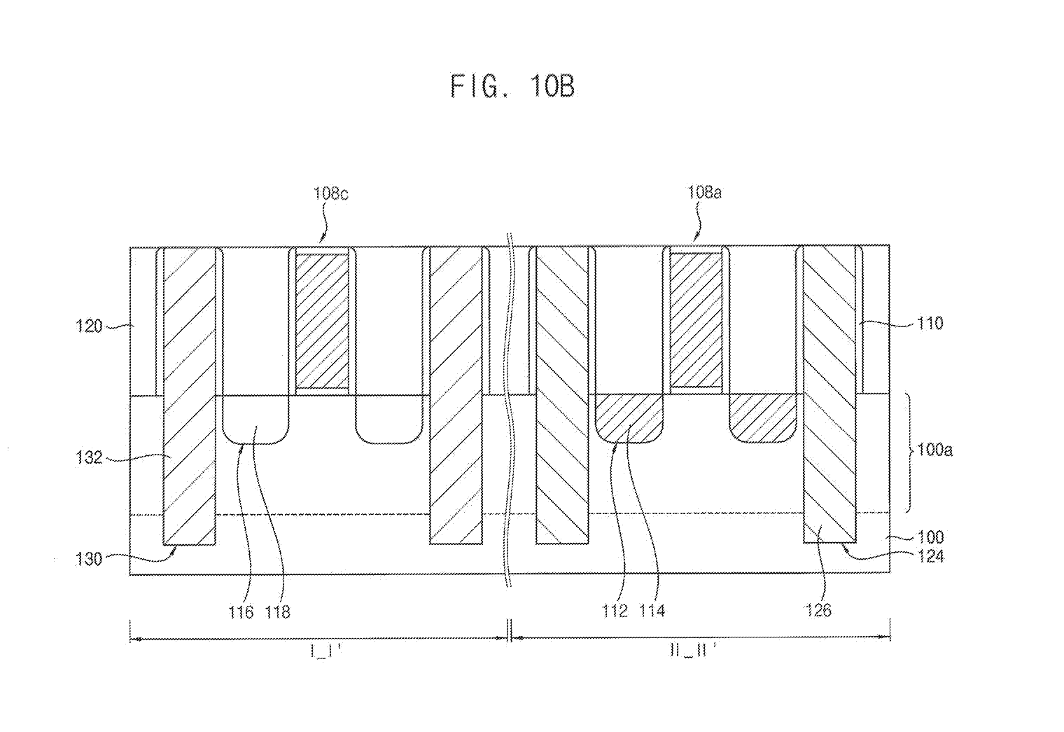

Referring to FIGS. 10A and 10B, a second insulation pattern 132 may be formed to fill the second trench 130. Particularly, a second insulation layer including a second insulation material may be formed to fill the second trench 130. The second insulation material may apply a tensile stress. In an example embodiment of the present invention, the second insulation material may include silicon nitride. In an example embodiment of the present invention, the second insulation layer may be formed by, e.g., a CVD process, an AID process, etc. In an example embodiment of the present invention, the first insulation material may include metal oxide or mixture of metal oxides. Combination of various metal oxides may alter the stress and may obtain high tensile stress values.

The second insulation layer may be planarized until upper surfaces of the first and second dummy gate structures 108a and 108c are exposed to form the second insulation pattern 132 in the second trench 130.

The second insulation pattern 132 may apply a tensile stress onto a channel region of the n-type transistor. The channel region may be a portion of the substrate 100 under the second dummy gate structure 108c. Also, a plurality of n-type transistors may be electrically isolated from each other by the second insulation pattern 132.

In an example embodiment of the present invention, the order of the process for forming the first insulation pattern 126 and the process for forming the second insulation pattern 132 may be changed. In an example embodiment of the present invention, only one of the process for forming the first insulation. pattern 126 and the process for forming the second insulation pattern 132 may be performed.

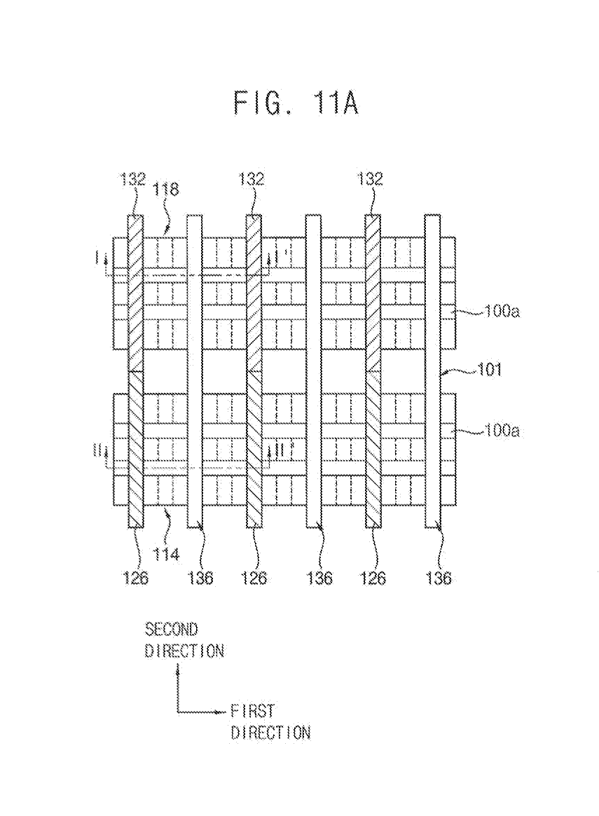

Referring to FIGS. 11A and 11B, a fifth etching mask 134 may be formed to expose only upper surfaces of the first and second dummy gate structures 108a and 108c.

The first and second dummy gate structures 108a and 108c may be etched using the fifth etching mask 134 to form a third trench 136. The third trench 136 may extend in the second direction across the first and second regions. A portion of the active fin. 100a may be exposed by the third trench 136.

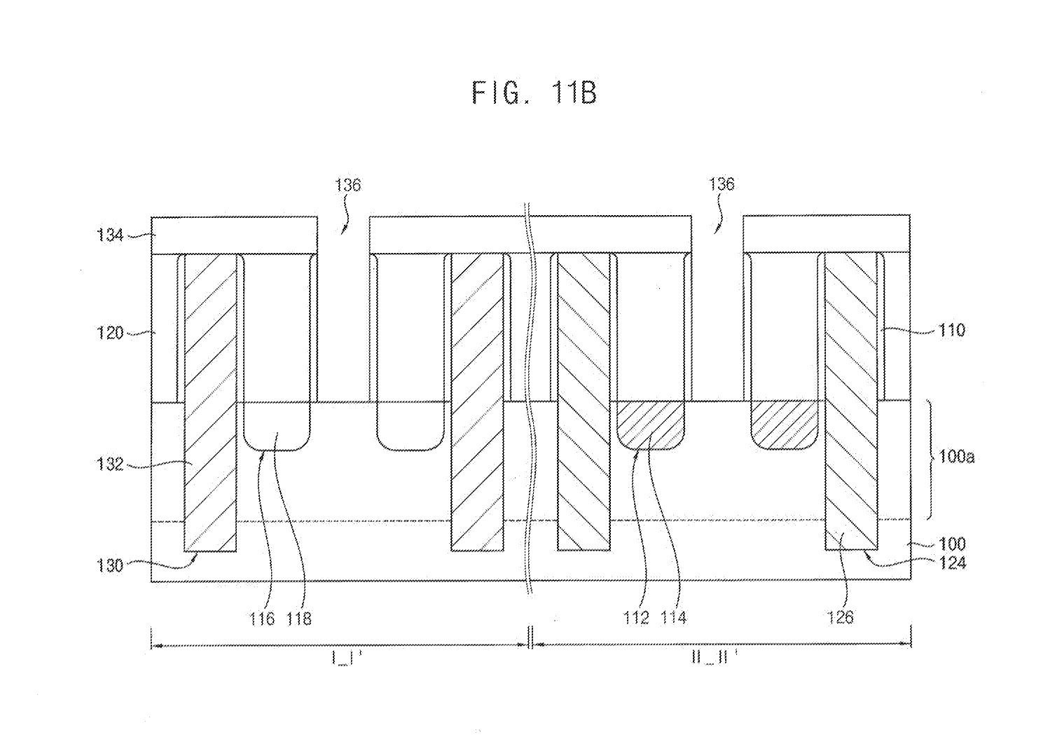

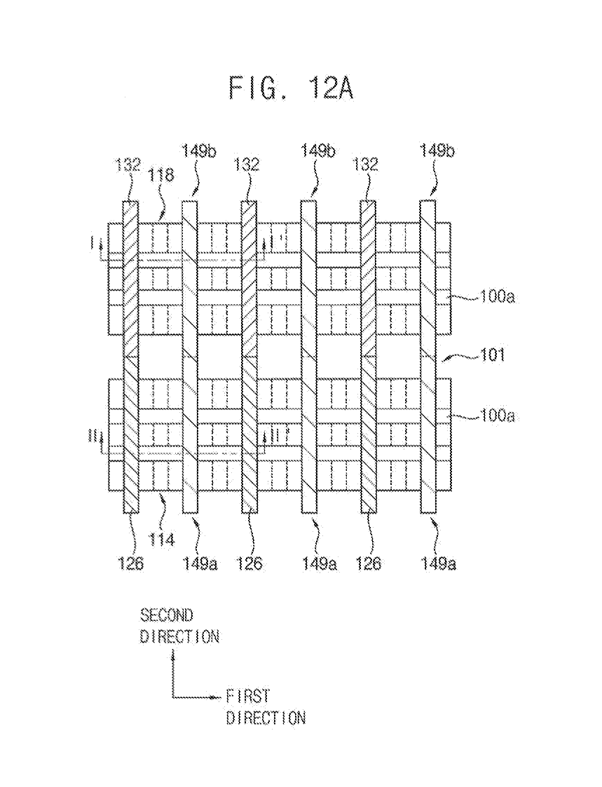

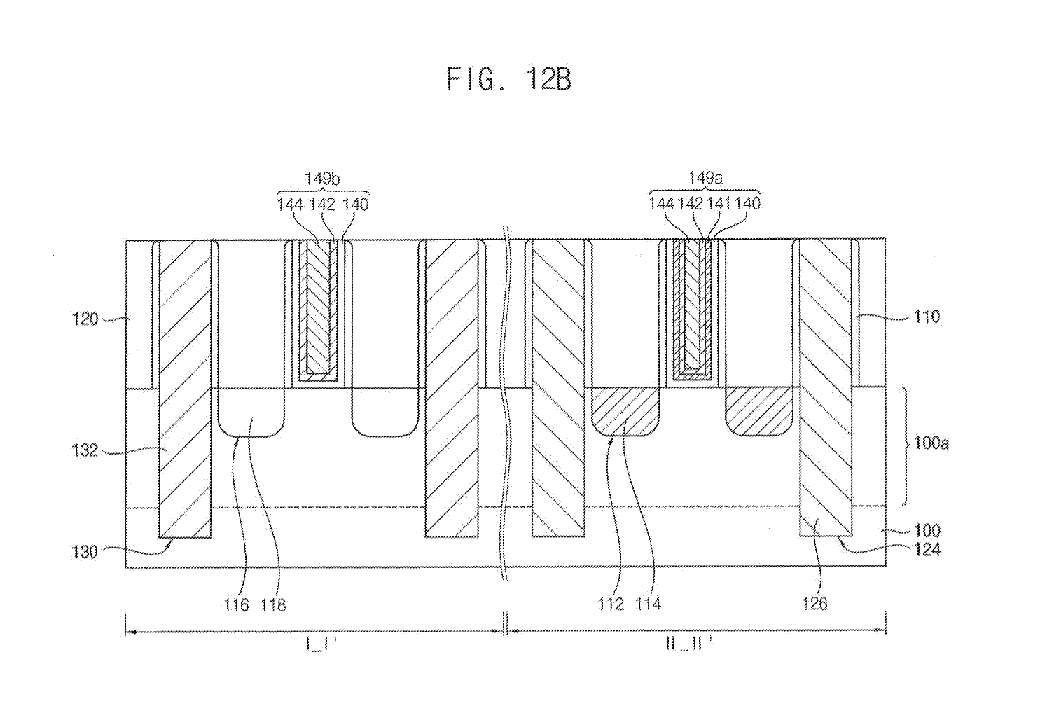

Referring to FIGS. 12A and 12B, a first preliminary gate structure 149a may be formed in the third trench 136 of the first region, and a second preliminary gate structure 149b may be formed in the third trench 136 of the second region.

A gate insulation layer may be conformally formed on an inner wall of the third trench 136 and the insulating interlayer 120. The gate insulation layer may be formed of a metal oxide having a dielectric constant higher than a dielectric constant of silicon nitride. The gate insulation layer may include, e.g., hafnium oxide (HfO₂), tantalum oxide (Ta₂O₅), zirconium oxide (Zr₂O₂), etc.

In an example embodiment of the present invention, before forming the gate insulation layer, an interface pattern may be further formed on a surface of the active fin 100a exposed by the third trench 136.

A first conductive layer may be conformally formed on the gate insulation layer, and a portion of the first conductive layer in the second region may be removed. A second conductive layer may be conformally formed on the first conductive layer in the first region and the gate insulation layer in the second region. Thus, the first and second conductive layers may be sequentially formed on the gate insulation layer in the first region, and the second conductive layer may be formed on the gate insulation layer in the second region. The first conductive layer may be formed of a metal or a metal alloy having a work function more than about 4.5 eV. The second conductive layer may be formed of a metal or a metal alloy having a work function less than about 4.5 eV.

A third conductive layer may be formed on the second conductive layer to fill the third trench 136. The third conductive layer may be formed of a metal, e.g., aluminum (Al), copper (Cu), tungsten (W), cobalt (Co), etc., or a metal nitride thereof.

The first, second and third conductive layers and the gate insulation layer may be planarized until an upper surface of the insulating interlayer 120 is exposed to form a preliminary first conductive pattern 141, a preliminary second conductive pattern 142, a preliminary third conductive pattern 144 and a preliminary gate insulation pattern 140, respectively. In an example embodiment of the present invention, the planarization process may be performed with a CMP process and/or an etch back process.

As a result of the above described processes, the first preliminary gate structure 149a including the preliminary gate insulation pattern 140, the preliminary first conductive pattern 141, the preliminary second conductive pattern 142 and the preliminary third conductive pattern 144 may be formed in the third trench 136 in the first region. A second preliminary gate structure 149b including the preliminary gate insulation pattern 140, the preliminary second conductive pattern 142 and the preliminary third conductive pattern 144 may be formed in the third trench 136 in the second region.

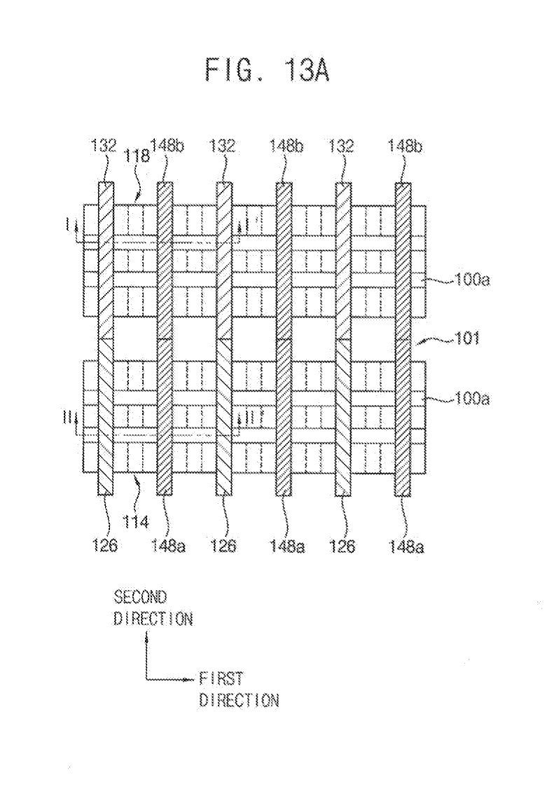

Referring to FIGS. 13A and 13B, upper portions of the preliminary gate insulation pattern 140, the preliminary first conductive pattern 141, the preliminary second conductive pattern 142 and the preliminary third conductive pattern 144 in the third trench 136 may be partially etched to form a recess. A hard mask layer may be formed to fill the recess. The hard mask layer may be planarized until the upper surface of the insulating interlayer 120 is exposed to form a hard mask 146. The file hard mask layer may be formed of a nitride, e.g., silicon nitride, silicon oxynitride, etc. Thus, a first gate structure 148a including a gate insulation pattern 140a, a first conductive pattern 141a, a second conductive pattern 142a, an electrode pattern 144a and the hard mask 146 may be formed in the third trench 136 in the first region. A second gate structure 148b including the gate insulation pattern 140a, the second conductive pattern 142a, the electrode pattern 144a and the hard mask 146 may be formed in the third trench 136 in the second region.

The first and second gate structures 148a and 148b may contact each other, so that the first and second gate structures 148a and 148b may be merged to form a gate structure. The gate structure may extend in the second direction across the first and second regions.

The gate structure, the first and second insulation patterns 126 and 132 may have the first width in the first direction.

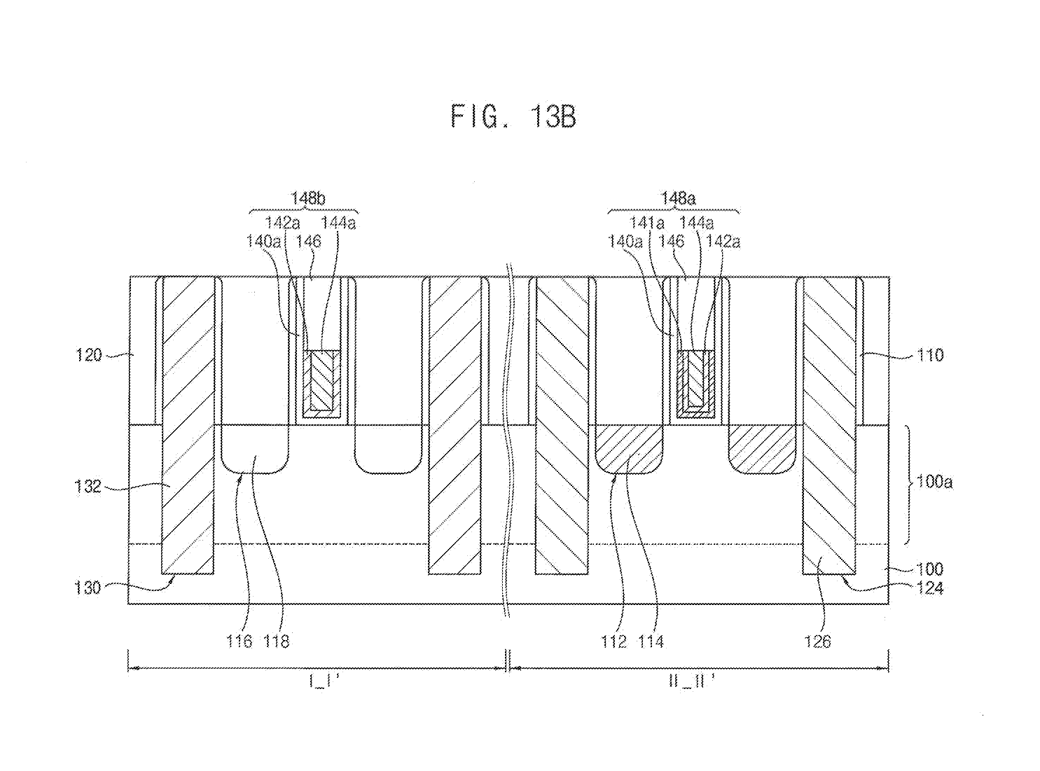

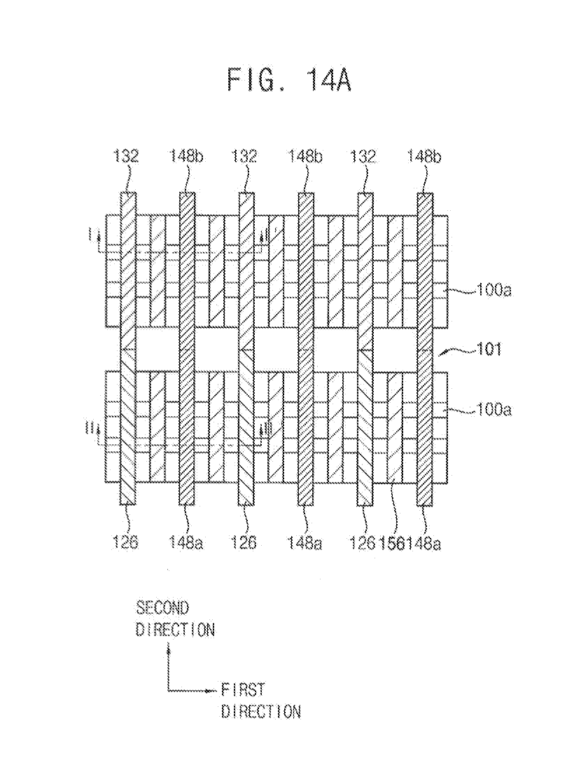

Referring to FIGS. 14A and 14B, a contact plug 156 may be formed through the insulating interlayer 120 on each of the first source/drain regions and the second source/drain regions.

A sixth etching mask may be formed on the insulating interlayer 120. The insulating interlayer 120 may be etched using the sixth etching mask to form a contact hole exposing each of the first source/drain regions and the second source/drain regions.

A barrier layer may be conformally formed on an inner wall of the contact hole, and a metal layer may be formed on the barrier layer to fill the contact hole. The barrier layer and the metal layer may be planarized until the upper surface of the insulating interlayer 120 is exposed to form the contact plug 156 including a barrier pattern 152 and a metal pattern 154.

As illustrated above, in the semiconductor device, the first insulation pattern 126 adjacent to both sides in the first direction of the p-type transistor and the second insulation pattern 132 adjacent to both sides in the first direction of the n-type transistor may include different materials from each other. Thus, each of the n-type transistor and the p-type transistor may have enhanced electrical characteristics.

FIG. 15 is a cross-sectional view illustrating a semiconductor device in accordance with an example embodiment of the present invention.

The semiconductor device of FIG. 15 may be substantially the same as or similar to the semiconductor device of FIGS. 1, 2, 3A and 3B, except for a second insulation pattern structure. Thus, like reference numerals refer to like elements, and detailed descriptions thereon may be omitted below in the interest of brevity.

Referring to FIG. 15, the substrate 100 may include the first region for forming a p-type transistor and the second region for forming an n-type transistor. A plurality of gate structures, the first source/drain regions, the second source/drain regions, the first insulation pattern 126 and a second insulation pattern structure 133 may be formed on the substrate 100. The first insulation pattern 126 may apply a compressive stress, and the second insulation pattern structure 133 may apply a tensile stress.

Each of the gate structures may extend in the second direction. A portion of the gate structure 148a formed in the first region may serve as a gate of the p-type transistor, and a portion of the gate structure 148b formed in the second region may serve as a gate of the n-type transistor. The gate of the p-type transistor is referred to as the first gate structure 148a, and the gate of the n-type transistor is referred to as the second gate structure 148b.

In an example embodiment of the present invention, the first epitaxial pattern 114 may be formed adjacent to the first gate structure 148a. The first epitaxial pattern 114 may be doped with p-type, impurities, so that the first epitaxial pattern 114 may serve as the first source/drain regions of the p-type transistor. In an example embodiment of the present invention, the second epitaxial pattern 118 may be formed adjacent to the second gate structure 148b. The second epitaxial pattern 118 may be doped with n-type impurities, so that the second epitaxial pattern 118 may serve as the second source/drain regions of the n-type transistor.

The first insulation pattern 126 may be formed between neighboring ones of the plurality of first gate structures 148a arranged in the first direction, so that a plurality of the p-type transistors including the first gate structures 148a may be electrically isolated from each other. The first insulation pattern 126 may be formed in the first region, and may extend in the second direction. The first insulation pattern 126 may include a first insulation material for applying a compressive stress. In an example embodiment of the present invention, the first insulation pattern 126 may include, e.g., silicon oxide.

The second insulation pattern structure 133 may be formed between neighboring ones of the plurality of second gate structures 148b arranged in the first direction, so that a plurality of the n-type transistors including the second gate structures 148b may be electrically isolated from each other. The second insulation pattern structure 133 may be formed in the second region, and may extend in the second direction.

The second insulation pattern structure 133 may include a second insulation liner pattern 132a and a second insulation pattern 132b. The second insulation liner pattern 132a may be formed directly on the substrate 100, and the second insulation pattern 132b may be formed on the second insulation liner pattern 132a. The second insulation liner pattern 132a may surround sidewalls and a bottom of the second insulation pattern 132b. Thus, a second insulation structure for applying a tensile stress may include the second insulation pattern 132 as described in the previous embodiment or the second insulation pattern structure 133 which includes the second insulation liner pattern 132a and the second insulation pattern 132b described above. In an example embodiment of the present invention, the second insulation pattern 132b may have a material substantially the same as a material of the first insulation pattern 126. Alternatively, the second insulation pattern 132b may have a material different from a material of the first insulation pattern 126.

In an example embodiment of the present invention, the second insulation liner pattern 132a may contain two or more layers including different materials in each layer. The multilayers of the second insulation liner pattern may apply a tensile stress to the channel region.

The second insulation liner pattern 132a may include a second insulation material for applying a tensile stress. In an example embodiment of the present invention, the second insulation liner pattern 132a may include, e.g., silicon nitride. The second insulation liner pattern 132a may apply the tensile stress onto the channel region of the n-type transistor. Since the channel region may correspond to a portion of the active fin 100a in the second active region, the portion (the second insulation liner pattern 132a) of the second insulation pattern structure 133 contacting the second active region of the substrate may include the second insulation material such as, e.g., silicon nitride to apply a tensile stress to the channel region of the n-type transistor. Thus, the charge mobilities of the p-type transistor and the n-type transistor may increase, respectively. A CMOS transistor including the n-type transistor and the p-type transistor may have enhanced electrical characteristics.

The contact plug 156 may be formed on each of the first source/drain regions and the second source/drain regions.

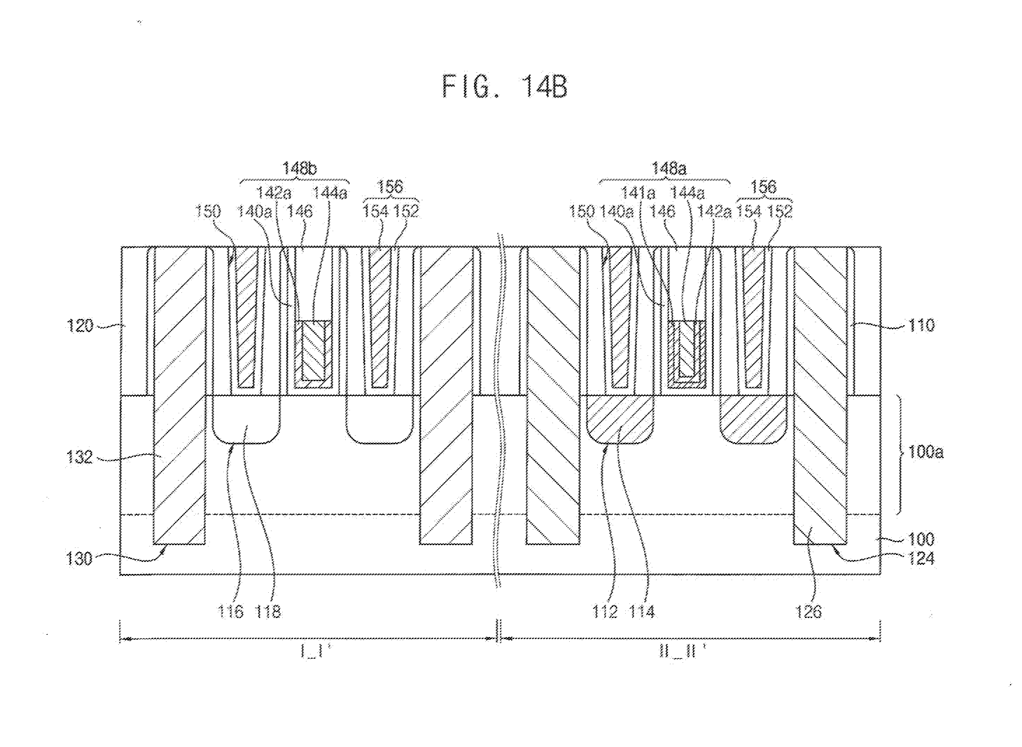

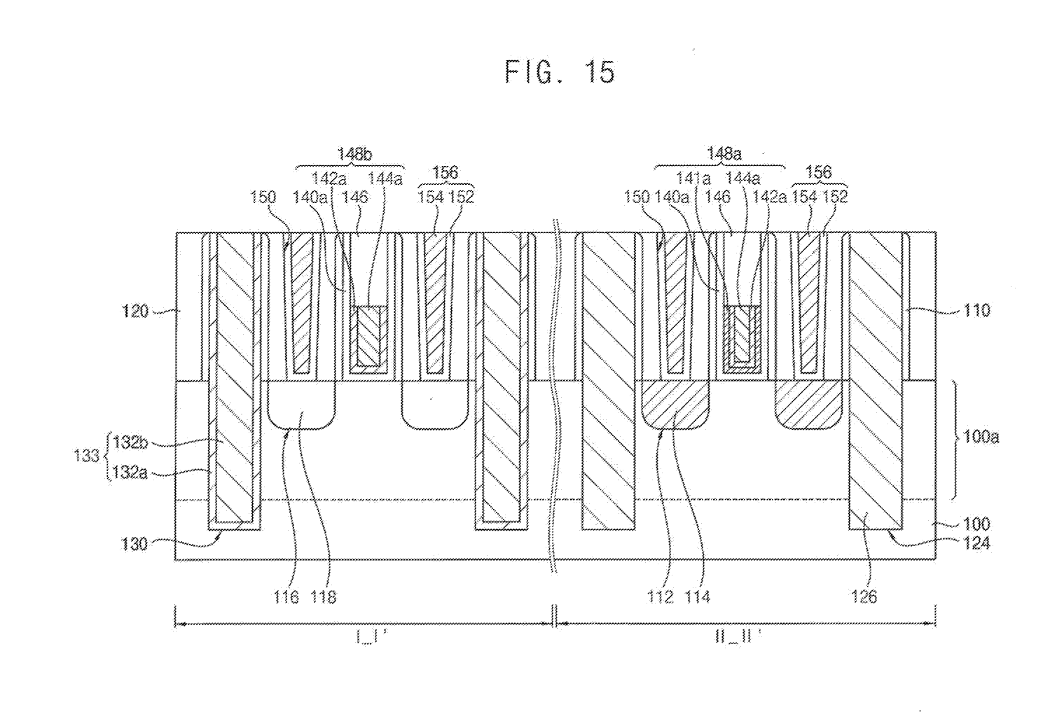

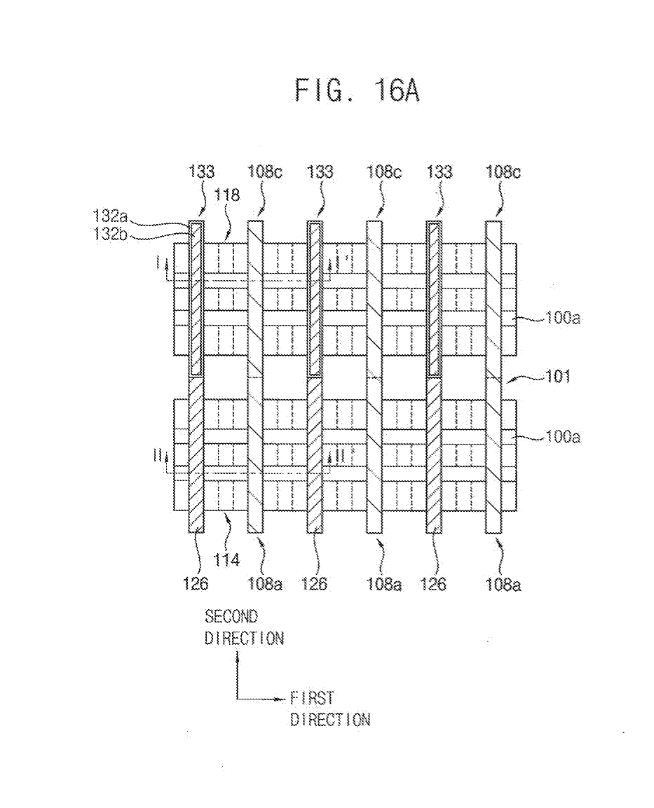

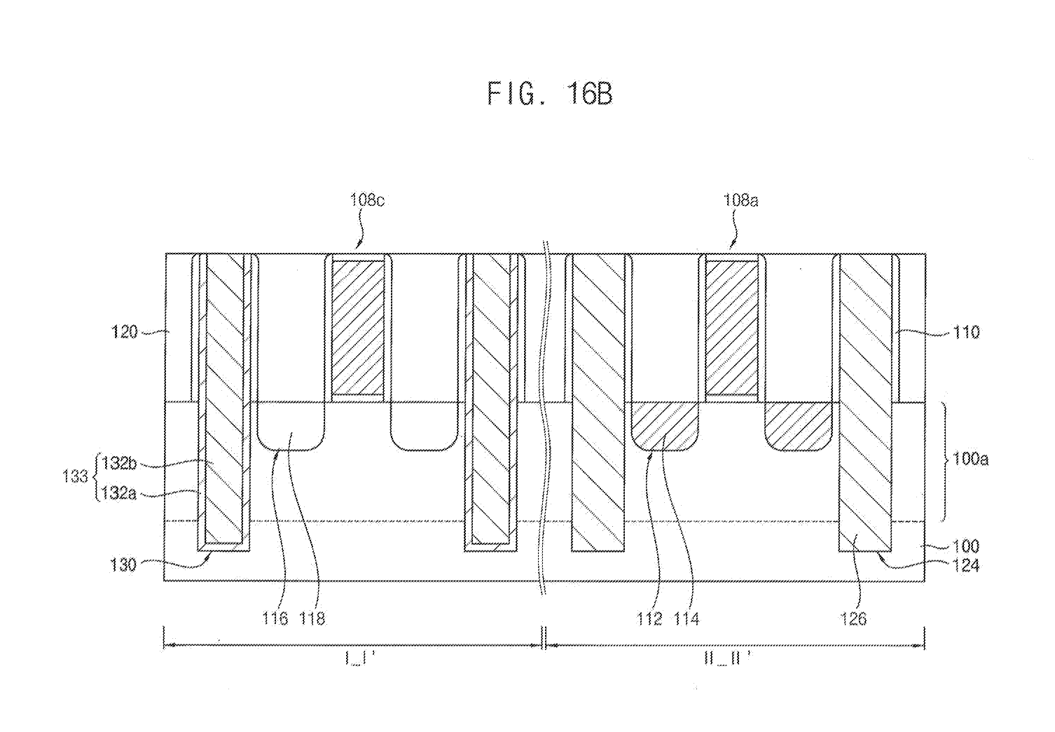

FIGS. 16A and 16B are a plan view and a cross-sectional view, respectively, illustrating stages of a method of manufacturing a semiconductor device in accordance with an example embodiment of the present invention. Particularly. FIG. 16B includes cross-sections taken along lines I-I′ and II-II′ of FIG. 16A.

This method as illustrated in FIGS. 16A and 16B may include processes substantially the same as or similar to those of the method illustrated with reference to FIGS. 4A to 14B, Thus, like reference numerals refer to like elements, and detailed descriptions thereon may be omitted below in the interest of brevity.

First, processes substantially the same as or similar to the processes illustrated with reference to FIGS. 4A to 9B may be performed. Thus, the first insulation pattern 126 and the second trench 130 may be formed on the substrate 100. The first insulation. pattern 126 may include th.e first insulation material.

Referring to FIGS. 16A and 16B, a second insulation liner layer may be conformally thrilled on an inner wall of the second trench 130 and the insulating interlayer 120. A first insulation layer may be formed on the second insulation liner layer to fill the second trench 130.

The second insulation liner layer may be formed of a second material for applying a tensile stress. In an example embodiment of the present invention, the second material may include, e.g., silicon nitride. The second insulation liner layer may be formed by, e.g., a CVD process, an ALD process, etc. The second insulation liner layer may apply the tensile stress onto the substrate under the second dummy gate structure 108c.

In an example embodiment of the present invention, the first insulation layer may include the first insulation material. Alternatively, the first insulation layer may include a. material different from the first insulation material.

The first insulation layer and the second insulation liner layer may be planarized until. upper surfaces of the first and second dummy gate structures 108a and 108c are exposed to form the second insulation pattern structure 133 in the second trench 130. The second insulation pattern structure 133 may include a second insulation liner pattern 132a and a second insulation pattern 132b.

After the process stage of FIGS. 16A and 16B, processes substantially the same as or similar to those illustrated with reference to FIGS. 11A to 14B may be performed to complete the semiconductor device.

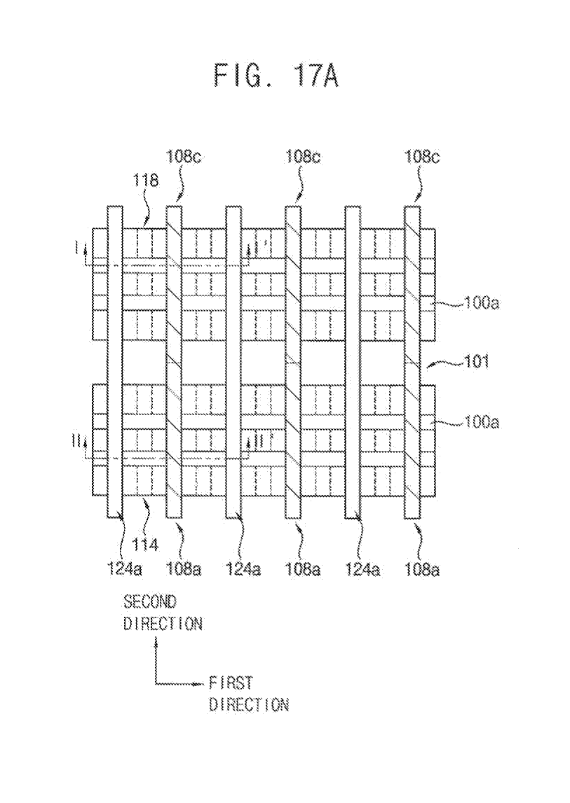

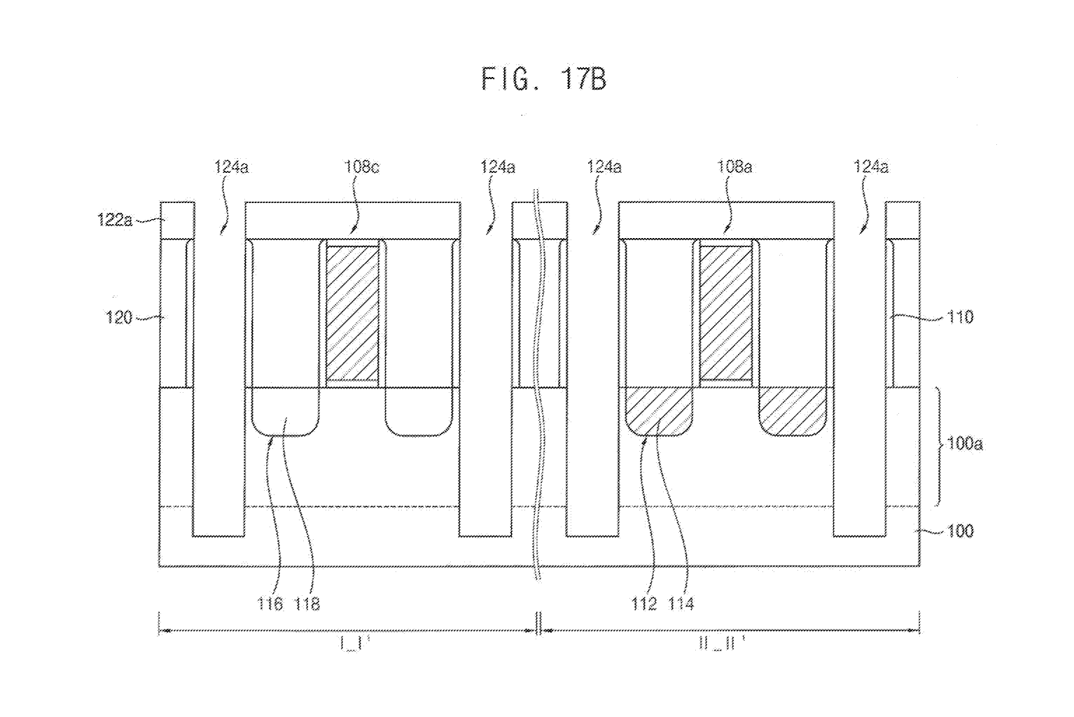

FIGS. 17A to 19B are plan views and cross-sectional views illustrating stages of a method of manufacturing a semiconductor device in accordance with an example embodiment of the present invention.

First, processes substantially the same as or similar to the processes illustrated with reference to FIGS. 4A to 6B may be performed. Thus, the first and second epitaxial patterns 114 and 118 may be formed on the substrate 100.

Referring to FIGS. 17A and 17B, an insulating interlayer 120 may be formed to cover the dummy gate structures 108a and 108c, the mold structures 108b and 108d, the first and second epitaxial patterns 114 and 118 and the isolation pattern 101.

A third etching mask 122a may be formed to expose only upper surfaces of the first and second mold structures 108b and 108d. The first and second mold structures 108b and 108d and the substrate 100 under the first and second mold structures 108b and 108d may be sequentially etched using the third etching mask to form a first trench 124a. A bottom of the first trench 124a may be lower than an upper surface of the substrate 100 between the active fins 100a. That is, the bottom of the first trench 124a may be lower than the bottom of the active fin 100a.

The third etching mask 122a may then be removed. Thus, the first and second dummy gate structures 108a and 108c may remain on the first and second regions, respectively.

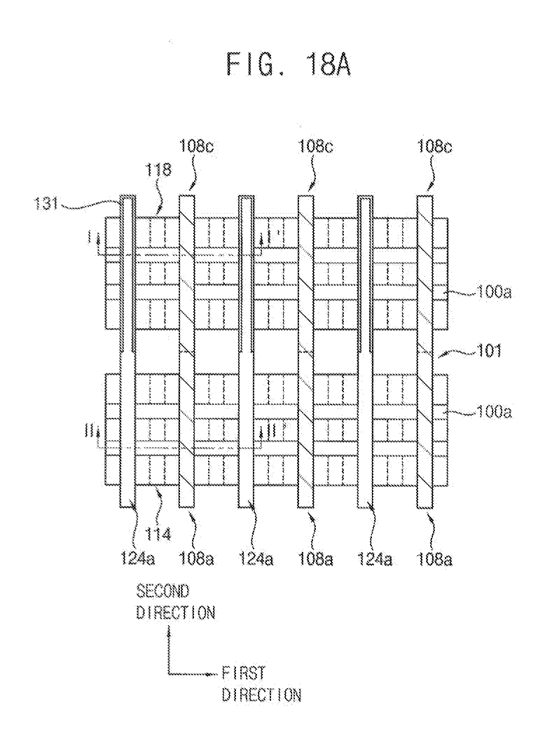

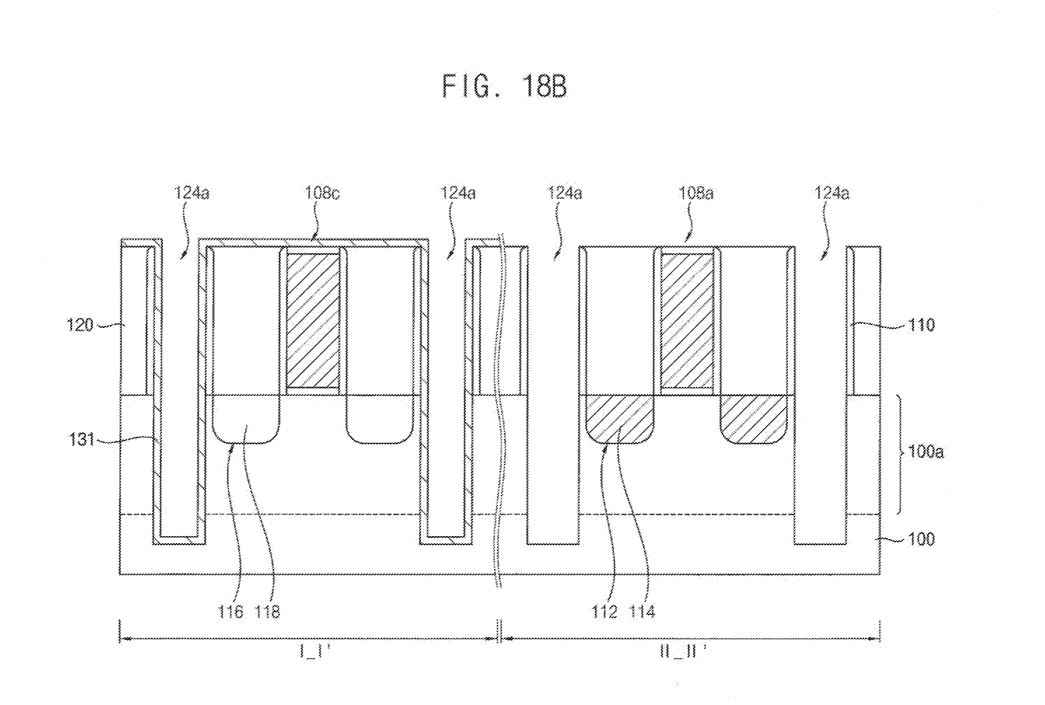

Referring to FIGS. 18A and 18B, a preliminary second insulation liner layer may be conformally formed on sidewalls and a bottom of the first trench 124a and the insulating interlayer 120. The preliminary second insulation liner layer may include a second material for applying a tensile stress. The preliminary second insulation liner layer may be formed by, e.g., a CVD process, an ALD process, etc. In an example embodiment of the present invention, the second material may include silicon nitride.

A portion of the preliminary second insulation liner layer formed in the first region may be removed to form a second insulation liner layer 131 on the sidewalls and the bottom of the first trench 124a and the insulating interlayer 120 in the second region. Alternatively, instead of forming the preliminary second insulation liner layer on sidewalls and a bottom of the first trench 124a in both first and second regions, the second insulation liner layer may only be formed on sidewalls and a bottom of the first trench 124a in the second region, then it may not need to remove the portion of the preliminary second insulation liner layer formed in the first region. On the other hand, formation of conformal layer only on one area may not be easy, and may require advanced selective CVD process or local silicon nitridation process.

Referring to FIGS. 19A and 19B, a first insulation layer may be formed on the second insulation liner layer 131 and the insulating interlayer 120 to fill the first trench 124a.

The first insulation layer including a first material for applying a compressive stress may be formed to fill the first trench 124a. In an example embodiment of the present invention, the first material may include silicon oxide. The first insulation layer may be formed by, e.g., a CVD process, a spin coating process, an ALD process, etc. In an example embodiment of the present invention, the first material may include metal oxide or mixture of metal oxides. Combination of various metal. oxides may alter the stress and may obtain high compressive stress values.

The first insulation layer may be planarized until upper surfaces of the first and second dummy gate structures 108a and 108c are exposed. Thus, a first insulation pattern 126 may be formed in the first trench 124a in the first region, and a second insulation pattern structure 133 including a second insulation liner pattern 132a and a second insulation pattern 132b may be formed in the first trench 124a in the second region. In this case, the second insulation pattern 132b may have a material substantially the same as a material of the first insulation pattern 126.

After the process stage of FIGS. 19A and 19B, processes substantially the same as or similar to those illustrated with reference to FIGS. 11A to 14B may be performed to complete the semiconductor device.

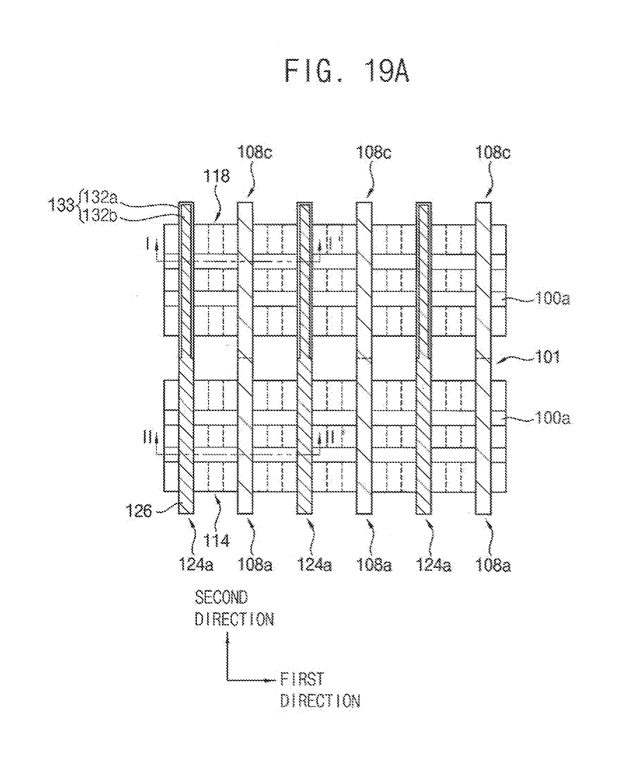

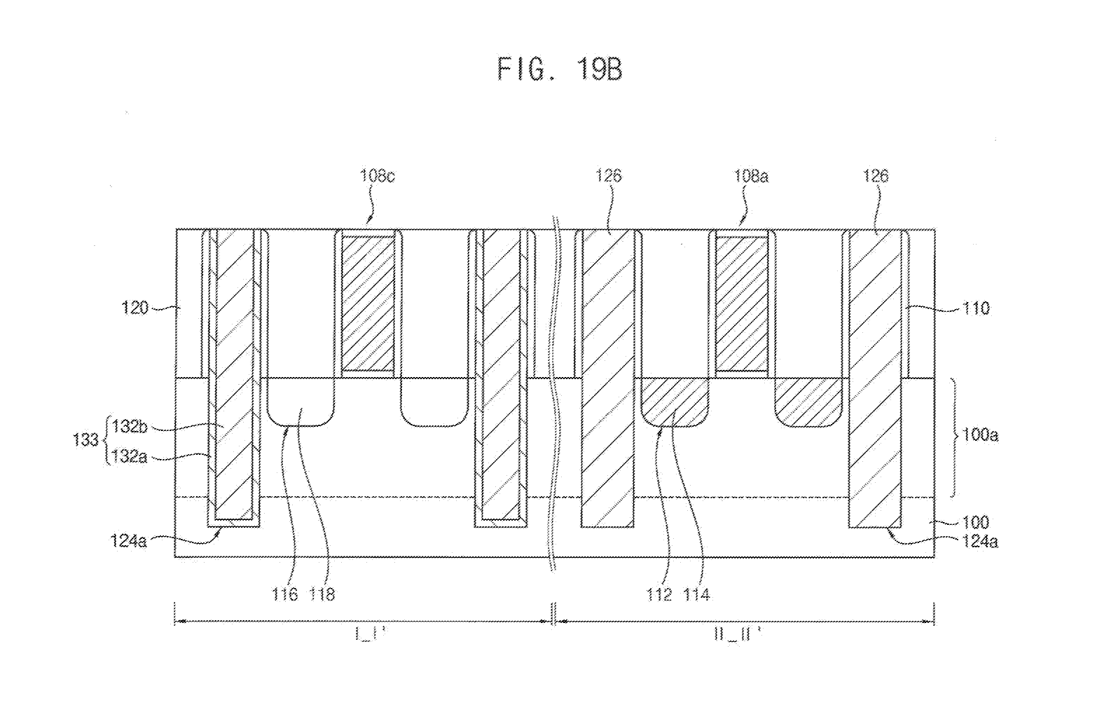

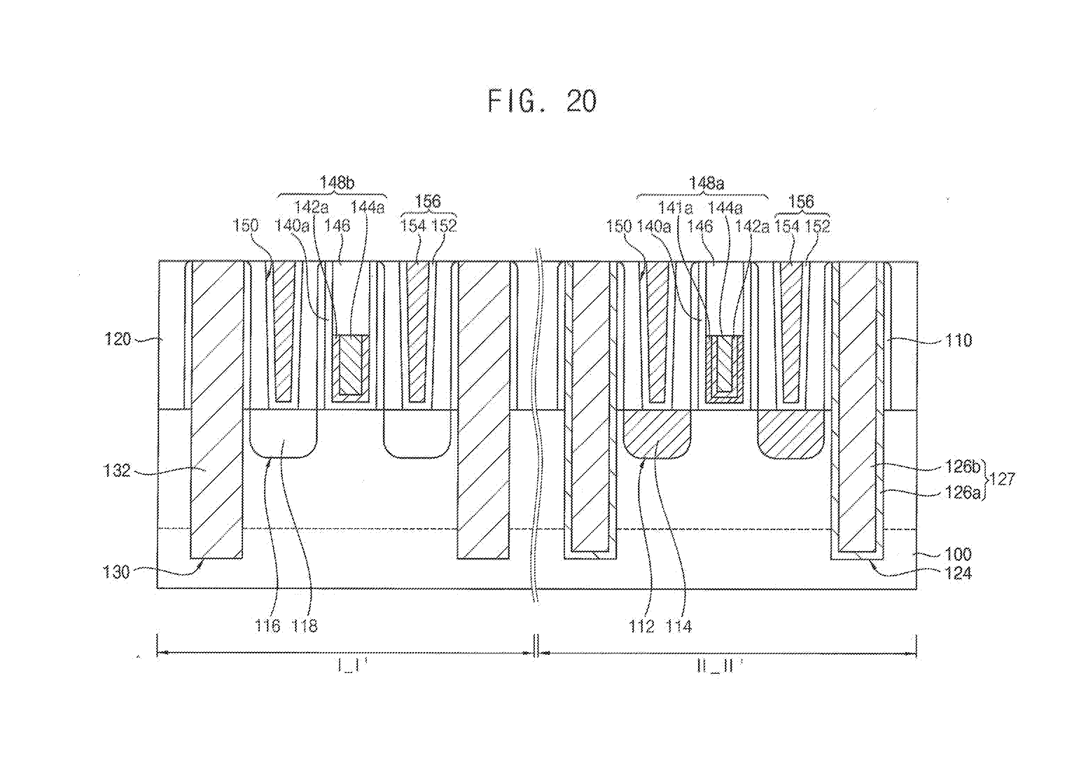

FIG. 20 is a cross-sectional view illustrating a semiconductor device in accordance with an example embodiment of the present invention.

The semiconductor device as illustrated in FIG. 20 may be substantially the same as or similar to the semiconductor device of FIGS. 1, 2, 3A and 3B, except for a first insulation pattern structure. Thus, like reference numerals refer to like elements, and detailed descriptions thereon may be omitted below in the interest of brevity.

Referring to FIG. 20, the substrate 100 may include the first region for forming a p-type, transistor and the second region for forming an n-type transistor. The first and second gate structures 148a and 148b, the first source/drain regions, the second source/drain regions, a first insulation pattern structure 127 and the second insulation pattern 132 may be formed on the substrate 100. The first insulation pattern structure 127 may apply a compressive stress, and the second insulation pattern 132 may apply a tensile stress.

The first insulation pattern structure 127 may be formed between neighboring ones of a plurality of first gate structures 148a arranged in the first direction, so that a plurality of the p-type transistors including the first gate structures 148a may be electrically isolated from each other. The first insulation pattern structure 127 may extend in the second direction. The first insulation pattern structure 127 may include a first insulation liner pattern 126a and a first insulation pattern 126b. The first insulation liner pattern 126a may be formed directly on the substrate 100, and the first insulation pattern 126b may be formed on the first insulation liner pattern 126a. The first insulation liner pattern 126a may surround sidewalls and a bottom of the first insulation pattern 126b. Thus, a first insulation structure for applying a compressive stress may include the first insulation pattern 126 as described in the previous embodiment or the first insulation pattern structure 127 which includes the first insulation liner pattern 126a and the first insulation pattern 126b described above.

In an example embodiment of the present invention, the first insulation liner pattern 126a may contain two or more layers including different materials in each layer. The multilayers of the first insulation liner pattern may apply a compressive stress to the channel region of the p-type transistor.

The first insulation liner pattern 126a may include a first insulation material for applying a compressive stress. In an example embodiment of the present invention, the first insulation liner pattern 126a may include, e.g., silicon oxide. The first insulation liner pattern 126a may apply the compressive stress onto the channel region of the p-type transistor. Since the channel region may correspond to a portion of the active fin 100a in the first active region, the portion (the first insulation liner pattern 126a) of the first insulation pattern structure 127 contacting the first active region of the substrate may include the first insulation material such as, e.g., silicon oxide to apply a compressive stress to the channel region of the p-type transistor.

The second insulation pattern 132 may be formed between neighboring ones of a plurality of second gate structures 148b arranged in the first direction, so that a plurality of the n-type transistors including the second gate structures 148b may be electrically isolated from each other. The second insulation pattern 132 may extend in the second direction.

The second insulation pattern 132 may include a second insulation material for applying a tensile stress. In an example embodiment of the present invention, the second insulation pattern 132 may include, e.g., silicon nitride.

In an example embodiment of the present invention, the second insulation pattern 132 may have a material substantially the same as a material of the first insulation pattern 126b. Alternatively, the second insulation pattern 132 may have a material different from a material of the first insulation pattern 126b.

As described above, the charge mobilities of the p-type transistor and the n-type transistor may be increased by the first insulation pattern structure 127 and the second insulation pattern 132, respectively. Thus, a CMOS transistor including the n-type transistor and the p-type transistor may have enhanced electrical characteristics.

In an example embodiment of the present invention, the second insulation pattern 132 described above may be replaced with the second insulation pattern structure 133 shown in FIG. 15. In this case, the substrate 100 may include the first region for forming a p-type transistor and the second region for forming an n-type transistor. The first and second gate structures 148a and 148b, the first source/drain regions, the second source/drain regions, the first insulation pattern structure 127 and the second insulation pattern structure 133 may be formed on the substrate 100. The first insulation pattern structure 127 may apply a compressive stress onto the channel region of the p-type transistor, and the second insulation pattern structure 133 may apply a tensile stress onto the channel region of the n-type transistor.

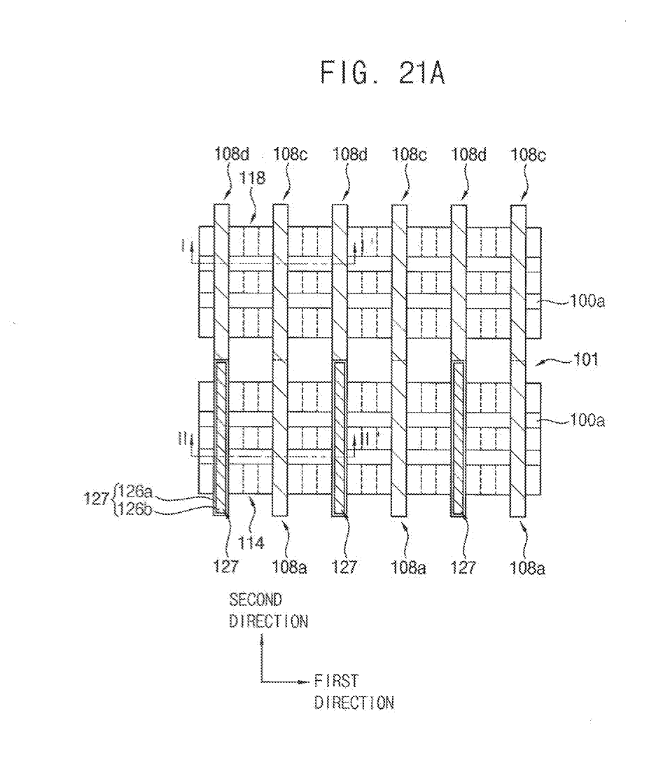

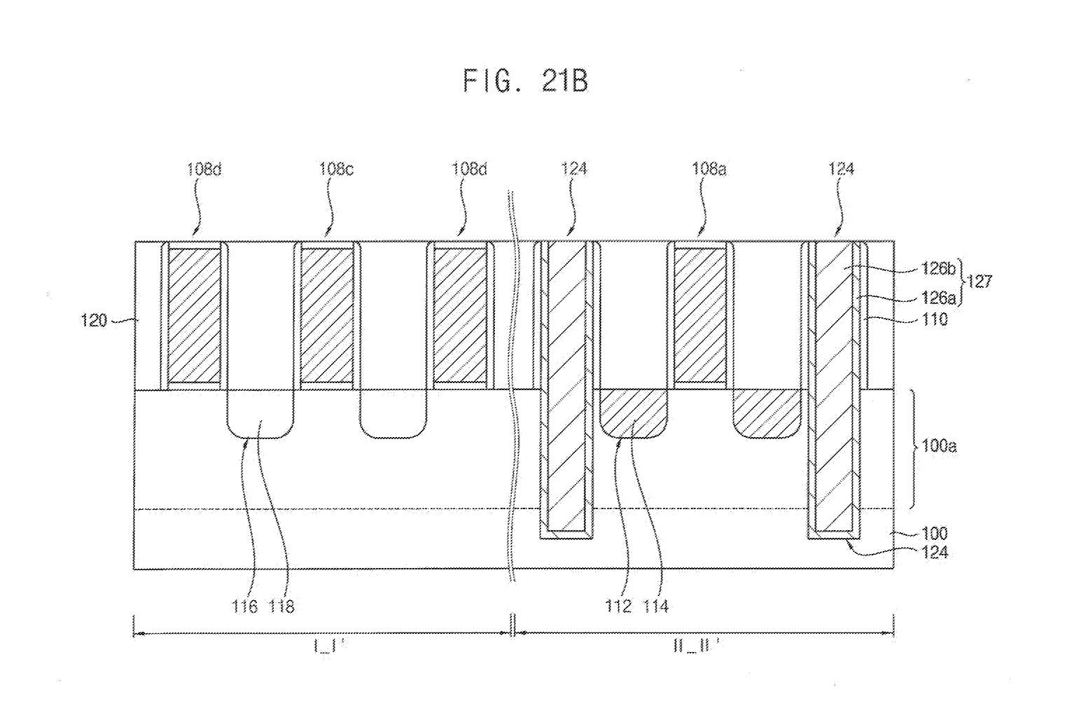

FIGS. 21A and 21B are a plan view and a cross-sectional view, respectively, illustrating stages of a method of manufacturing a semiconductor device in accordance with an example embodiment of the present invention.

First, processes substantially the same as or similar to the processes illustrated with reference to FIGS. 4A to 7B may be performed. Thus, the first trench 124 may be formed on the substrate 100.

Referring to FIGS. 21A and 21B, a first insulation liner layer may be conformally formed on an inner wall of the first trench 124 and the insulating interlayer 120. A first insulation layer may be formed on the first insulation liner layer to fill the first trench 124.

The first insulation liner layer may include a first material for applying a compressive stress. In an example embodiment of the present invention, the first material may include silicon oxide. The first insulation liner layer may be formed by, e.g., a CVD process, an ALD process, etc. Thus, the compressive stress may be applied to a portion of the substrate 100 under the first dummy gate structure 108a by the first insulation liner layer.

The first insulation layer and the first insulation liner layer may be planarized until upper surfaces of the first and second dummy gate structures 108a and 108c are exposed to form a first insulation pattern structure 127 including a first insulation liner pattern 126a and a first insulation pattern 126b in the first trench 124.

After the process stage of FIGS. 21A and 21B, processes substantially the same as or similar to those illustrated with reference to FIGS. 9A to 14B may be performed to complete the semiconductor device.

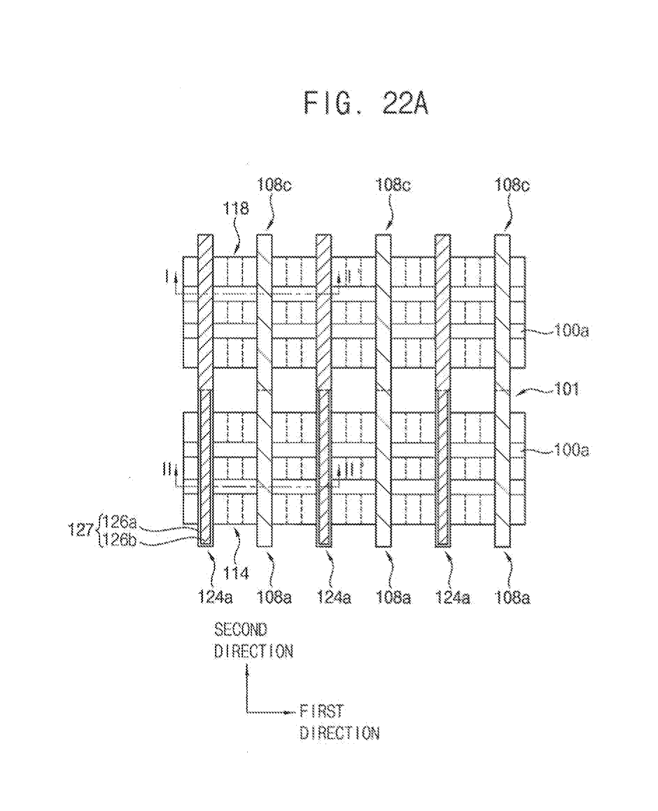

FIGS. 22A and 22B are a plan view and a cross-sectional view, respectively, illustrating stages of a method of manufacturing a semiconductor device in accordance with an example embodiment of the present invention.

First, processes substantially the same as or similar to the processes illustrated with reference to FIGS. 4A to 6B may be performed. Thus, the first and second epitaxial patterns 114 and 118 may be formed on the substrate 100. The first and second mold structures 108b and 108d and the substrate 100 under the first and second mold structures 108b and 108d may be etched to form a first trench 124a, as illustrated with reference to FIGS. 17A and 17B.

Referring to FIGS. 22A and 22B, a preliminary first insulation liner layer may be conformally formed on sidewalls and a bottom of the first trench 124a and the insulating interlayer 120. A preliminary first insulation liner layer may include a first material for applying a compressive stress. The first insulation liner layer may be formed by, e.g., a CVD process, an AID process, etc. In an example embodiment of the present invention, the first material may include silicon oxide.

A portion of the preliminary first insulation liner layer in the second region may be etched to form a first insulation liner layer. The first insulation liner layer may be formed on the sidewalls and the bottom of the first trench 124a and the insulating interlayer 120 in the first region. Alternatively, instead of forming the preliminary first insulation liner layer on sidewalls and a bottom of the first trench 124a in both first and second regions, the first insulation liner layer may only be formed on sidewalls and a bottom of the first trench 124a in the first region, then it may not need to remove the portion of the preliminary first insulation liner layer formed in the second region. On the other hand, formation of conformal layer only on one area may not be easy, and may require advanced selective CVD process or local silicon oxidation process.

A second insulation layer may be formed on the insulating interlayer 120 and the first insulation liner layer to fill the first trench 124a. Particularly, the second insulation layer including a second material may be formed to fill the first trench 124a. The second insulation material may be a material for applying a tensile stress. In. an example embodiment of the present invention, the second material may include, e,g., silicon nitride. The second insulation. layer may be formed by, e.g., a CVD process, an ALD process, etc. In an example embodiment of the present invention, the second material may include metal oxide or mixture of metal oxides. Combination of various metal oxides may alter the stress and may obtain high tensile stress values.

The second insulation layer may be planarized until upper surfaces of the first and second dummy gate structures 108a and 108c are exposed. Thus, a first insulation pattern structure 127 including the first insulation liner pattern 126a and a first insulation pattern 126b may be formed in the first trench 124a in the first region, and a second insulation pattern 132 may be formed in the first trench 124a in the second region. In this case, the first insulation pattern 126b may have a material substantially the same as a material of the second insulation pattern 132.

After the process stage of FIGS. 22A and 22B, processes substantially the same as or similar to those illustrated with reference to FIGS. 11A to 14B may be performed to complete the semiconductor device.

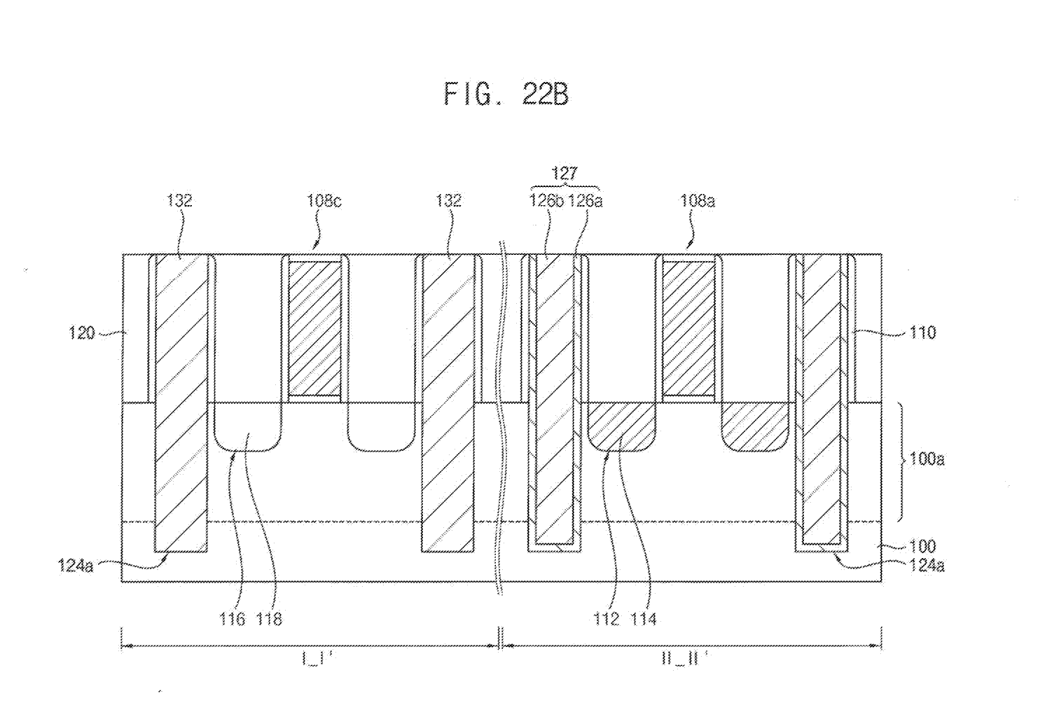

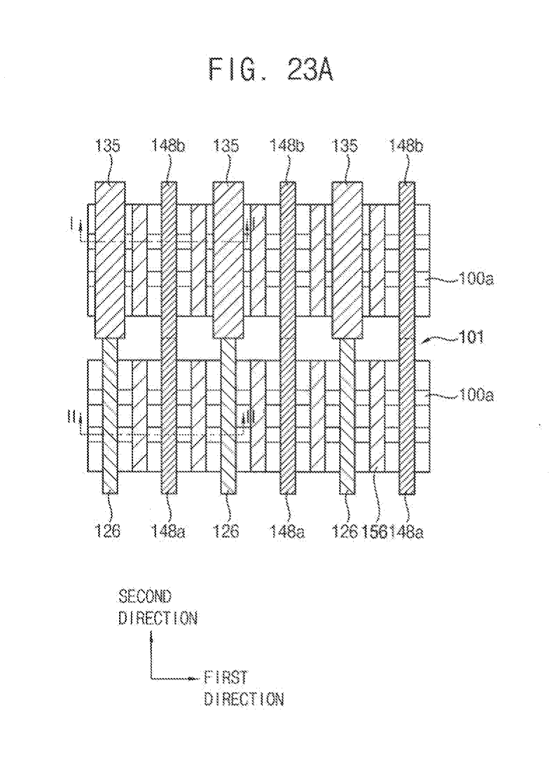

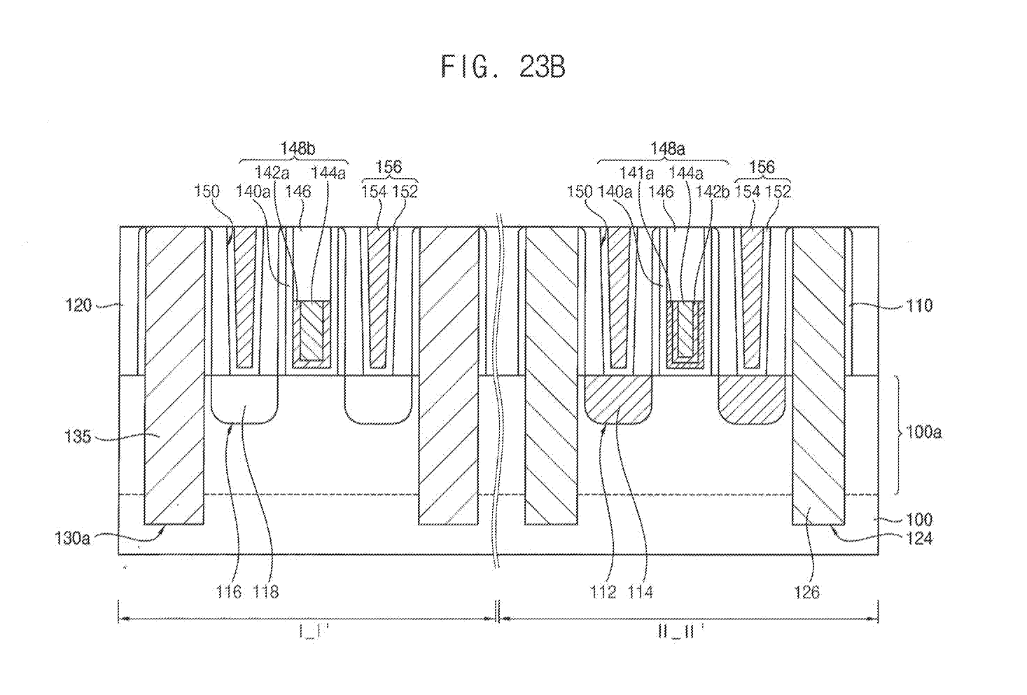

FIGS. 23A and 23B are a plan view and a cross-sectional view, respectively, illustrating a semiconductor device in accordance with an example embodiment of the present invention. Particularly. FIG. 23B includes cross-sections taken along lines I-I′and II-II′ of FIG. 23A.

The semiconductor device illustrated in FIGS. 23A and 23B may be substantially the same as or similar to the semiconductor device of FIGS. 1, 2, 3A and 3B, except for a second insulation pattern. Thus, like reference numerals refer to like elements, and detailed descriptions thereon may be omitted below in the interest of brevity.

Referring to FIGS. 23A to 23B, the substrate 100 may include the first region for forming a p-type transistor and the second region for forming an n-type transistor. The first and second gate structures 148a and 148b, the first source/drain regions, the second source/drain regions, the first insulation pattern 126 and a second insulation pattern 135 may be formed on the substrate 100. The first insulation pattern 126 may apply a compressive stress, and the second insulation pattern 135 may apply a tensile stress.

The first insulation pattern 126 may be formed between neighboring ones of a plurality of first gate structures 148a arranged in the first direction, so that a plurality of the p-type transistors including the first gate structures 148a may be electrically isolated from each other. The first insulation pattern 126 may have a first width in the first direction, and may extend in the second direction. The first insulation pattern 126 may include a first material for applying a compressive stress. In an example embodiment of the present invention, the first insulation pattern 126 may include, e.g., silicon oxide.

The second insulation pattern 135 may be formed between neighboring ones of a plurality of second gate structures 148b arranged in the first direction, so that a plurality of the n-type transistors including the second gate structures 148b may be electrically isolated from each other. The second insulation pattern 135 may have a second width in the first direction different from the first width, and may extend in the second direction. In an example embodiment of the present invention, the second width may be greater than the first width. Alternatively, the second width may be less than the first width.

The second insulation pattern 135 may include a second insulation material for applying a tensile stress. The tensile stress applied onto the n-type transistor may be controlled by the second width of the second insulation pattern 135. In an example embodiment of the present invention, when the second width is greater than the first width, the tensile stress may be larger. Alternatively, when the second width is less than the first width, the compressive stress may be larger.

As described above, the charge mobilities of the p-type transistor and the n-type transistor may be increased by the first insulation pattern 126 and the second insulation pattern 135, respectively. Thus, a CMOS transistor including the n-type transistor and the p-type transistor may have enhanced electrical characteristics.

The contact plug 156 may be formed on each of the first source/drain regions and the second source/drain regions.

The semiconductor as illustrated in FIGS. 23A and 23B may be manufactured by performing processes substantially the same as or similar to the processes illustrated with reference to FIGS. 4A to 14B.

In an example embodiment of the present invention, the second trench may be formed to have a second width greater than a first width of the first trench. Alternatively, when the dummy gate structure and the mold structure are formed, the first mold structure may be formed to have a first width in the first direction, and the second mold structure may be formed to have a second width different from the first width. Thus, the semiconductor device may be formed on the substrate.

In an example embodiment of the present invention, the second insulation pattern 135 described above may be replaced with a second insulation pattern structure similar to the second insulation pattern structure 133 shown in FIG. 15 except having a dissimilar width. The second insulation pattern structure having a dissimilar width may include a second insulation liner pattern. and a second insulation pattern, and may have a third width in the first direction different from the first width, and may extend in the second direction. The second insulation liner pattern may include a second insulation material for applying a tensile stress. The third width may be greater than the first width. Alternatively, th.e third width may be less than the first width.

The width described above may be altered. For example, the second insulation pattern structure may have the first width, and the first insulation pattern 126 may have the third width. In addition, the first width may or may not be equal to the width of the first and second gate structures 148a and 148b.

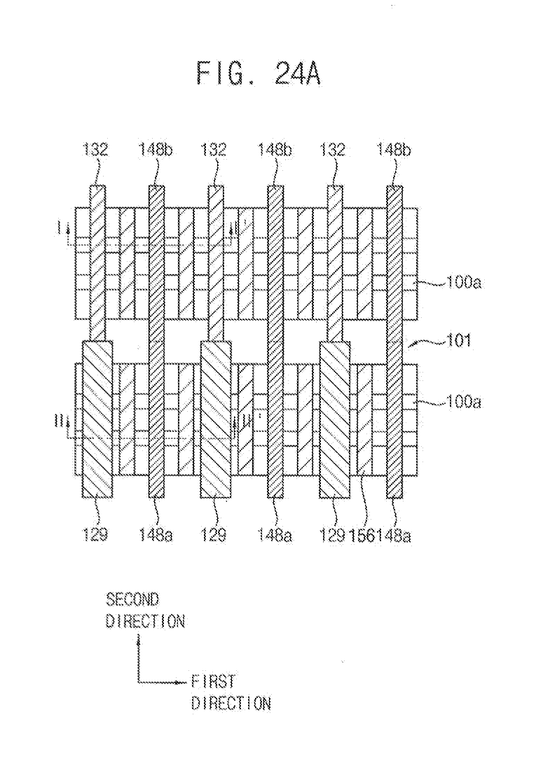

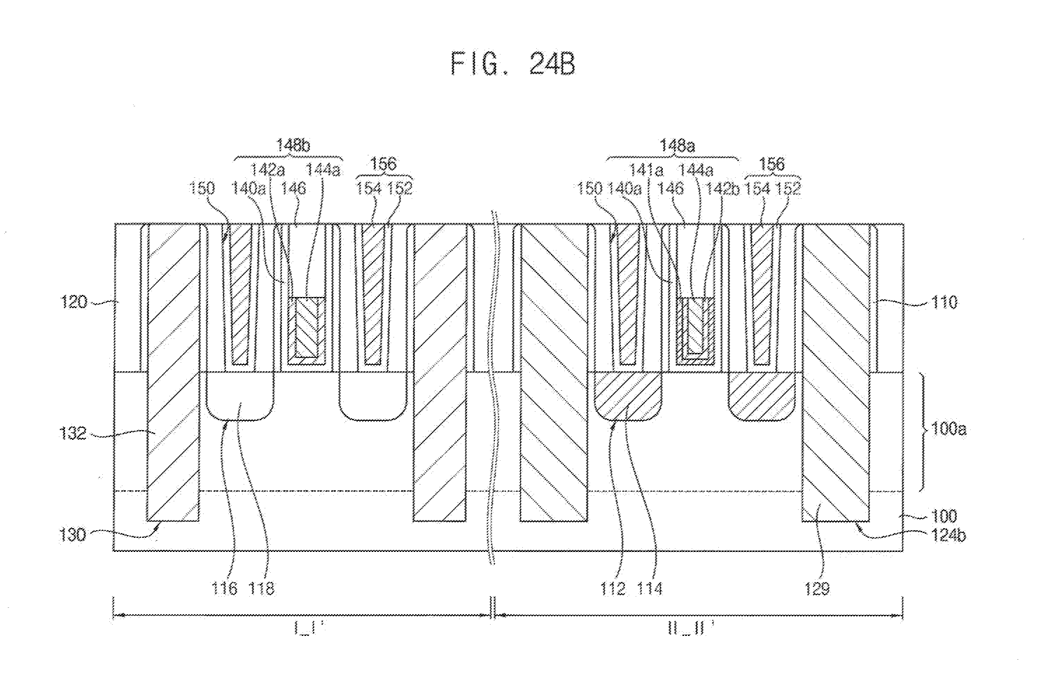

FIGS. 24A and 24B are a plan view and a cross-sectional view, respectively, illustrating a semiconductor device in accordance with an example embodiment of the present invention. Particularly. FIG. 24B includes cross-sections taken along lines I-I′ and II-II′ of FIG. 24A.

The semiconductor device illustrated in FIGS. 24A and 24B may be substantially the same as or similar to the semiconductor device of FIGS. 1. 2, 3A and 3B, except for a first insulation pattern. Thus, like reference numerals refer to like elements, and detailed descriptions thereon may be omitted below in the interest of brevity.

Referring to FIGS. 24A to 24B, the substrate 100 may include the first region for forming a p-type transistor and the second region for forming an n-type transistor. The first and second gate structures 148a and 148b, the first source/drain regions, the second source/drain regions, a first insulation pattern 129 and the second insulation pattern 132 may be formed on the substrate 100. The first insulation pattern 129 may apply a compressive stress, and the second insulation pattern 132 may apply a tensile stress.

The first and second gate structures 148a and 148b may have a first width in the first direction.

The first insulation pattern 129 may be formed between neighboring ones of a plurality of first gate structures 148a arranged in the first direction, so that a plurality of the p-type transistors including the first gate structures 148a. and 148b may be electrically isolated from each other. The first insulation pattern 129 may have a second width in the first direction different from the first width, and may extend in the second direction. In an example embodiment of the present invention, the second width may be greater than the first width. Alternatively, the second width may be less than the first width.

The second insulation pattern 132 may be formed between neighboring ones of a plurality of second gate structures 148b arranged in the first direction, so that a plurality of the n-type transistors including the second gate structures 148b may be electrically isolated from each other. The second insulation pattern 132 may have the first width in the first direction, and may extend in the second direction.

The second insulation pattern 132 may include a second insulation material for applying a tensile stress.

As described above, the charge mobilities of the p-type transistor and the as-type transistor may be increased by the first insulation pattern 129 and the second insulation pattern 132, respectively. Thus, a CMOS transistor including the n-type transistor and the p-type transistor may have enhanced electrical characteristics.

The contact plug 156 may be formed on each of the first source/drain regions and the second source/drain regions.

The semiconductor illustrated in FIGS. 24A and 24B may be manufactured by performing processes substantially the same as or similar to the processes illustrated with reference to FIGS. 4A to 14B.

In an example embodiment of the present invention, the first trench may be formed to have a width greater than a width of the second mold structure. Alternatively, when the dummy gate structure and the mold structure are formed, the first mold structure may be formed to have the second width in the first direction, and the second mold structure may be formed to have the first width in the first direction. Thus, the semiconductor device may be formed on the substrate.

In an example embodiment of the present invention, the first insulation pattern 129 described above may be replaced with a first insulation pattern structure similar to the first insulation pattern structure 127 shown in FIG. 20 except having a dissimilar width. The first insulation pattern structure having a dissimilar width may include a first insulation liner pattern and a first insulation pattern, and may have a fourth. width in the first direction different from the first width, and may extend in the second direction. The first insulation liner pattern may include a first insulation material for applying a compressive stress. The fourth width may be greater than the first width. Alternatively, the fourth width may be less than the first width.

The width described above may be altered. For example, the first insulation pattern structure may have the first width which may be the width of the first and second gate structures 148a and 148b, and the second insulation. pattern 126 may have the fourth width. In addition, the first and second gate structures 148a and 148b may have a width different from the first width.

In an example embodiment of the present invention, the substrate 100 may include the first region for forming a p-type transistor and the second region for forming an n-type transistor. The first and second gate structures 148a and 148b, the first source/drain regions, the second source/drain regions, the first insulation pattern structure 127 and the second insulation pattern structure 133 may be formed on the substrate 100. The first insulation pattern structure 127 described here has a structure the same as that of the first insulation pattern structure 127 shown in FIG. 20 except that the width may be different. The second insulation pattern structure 1.33 described here has a structure the same as that of the second insulation pattern structure 133 shown in FIG. 15 except that the width may be different. The first insulation pattern structure 127 may apply a compressive stress onto the Channel region of the p-type transistor, and the second insulation pattern structure 133 may apply a tensile stress onto the channel region of the n-type transistor. The first insulation pattern structure 12.7 may have a fifth width and the second insulation pattern structure 133 may have a sixth width. The sixth width may be greater than the fifth width. Alternatively, the sixth width may be less than the fifth width.

The semiconductor device may be applied to memory devices and/or logic devices including transistors.

The foregoing is illustrative of example embodiments of the present invention and is not to be construed as limiting thereof. Although a few example embodiments of the present invention have been described, those skilled in the art will readily appreciate that many modifications are possible in the example embodiments without materially departing from the novel teachings of the present inventive concept. Accordingly, all such modifications are intended to be included within the scope of the present inventive concept as defined in the claims. Therefore, it is to be understood that the foregoing is illustrative of various example embodiments of the present invention and is not to be construed as limited to the specific example embodiments disclosed, and that modifications to the disclosed example embodiments, as well as other example embodiments, are intended to be included within the scope of the appended claims

What is claimed is:

1. A semiconductor device, comprising:
a plurality of active fins in a substrate, wherein each of the plurality of active fins protrudes from a substrate, and extends in a first direction;
a gate structure on the active fins, the gate structure extending in a second direction perpendicular to the first direction to cross over the active fins; and
a plurality of first insulation structures extending in the second direction in parallel with the gate structure, the first insulation structures being spaced apart from both sides in the first direction of the gate structure, respectively,
wherein one gate structure is formed between two first insulation structures, and
wherein lower surfaces of the first insulation structures are lower than upper surfaces of the active fins, and upper surfaces of the first insulation structures and the gate structure are coplanar with each other.

2. The semiconductor memory device of claim 1, further comprising:
an impurity region between the gate structure and each of the first insulation structures; and
a contact plug contacting the impurity region.

3. The semiconductor memory device of claim 2, wherein an upper surface of the contact plug is coplanar with the upper surfaces of the first insulation structures and the gate structure.

4. The semiconductor memory device of claim 2, wherein the contact plug is formed between each of the first insulation structures and the gate structure, and the contact plug is spaced apart from a side of each of the first insulation structures and the gate structure.

5. The semiconductor memory device of claim 1, wherein each of the active fins includes a recess between each of first insulation structures and the gate structure, and a first epitaxial pattern serving as an impurity region is formed in the recess.

6. The semiconductor device of claim 5, wherein the first epitaxial pattern includes a silicon germanium doped with p-type impurities.

7. The semiconductor device of claim 5, wherein the first epitaxial pattern includes silicon doped with n-type impurities.

8. The semiconductor memory device of claim 1,
wherein the gate structure includes a gate insulation pattern, a conductive pattern, an electrode pattern and a hard mask sequentially stacked, and
wherein the conductive pattern includes a metal for adjusting a threshold voltage.

9. The semiconductor memory device of claim 1, further comprising:
first spacers on sidewalls of the gate structure; and
second spacers on sidewalls of the first insulation structures.

10. The semiconductor memory device of claim 9, wherein the first spacers include a material substantially the same as a material of the second spacers.

11. The semiconductor memory device of claim 9, wherein the first and second spacers include silicon nitride or silicon oxynitride.

12. The semiconductor memory device of claim 1, wherein each of the first insulation structures includes an insulation material for applying a tensile stress or an insulation material for applying a compressive stress.

13. The semiconductor memory device of claim 1, wherein each of the first insulation structures includes a first insulation pattern extending in the second direction and a liner pattern on a sidewall and a lower surface of the first insulation pattern, and the liner pattern includes a material different from a material of the first insulation pattern.

14. The semiconductor memory device of claim 13, wherein the liner pattern includes an insulation material for applying a tensile stress or an insulation material for applying a compressive stress.

15. A semiconductor device, comprising:
a substrate including a first region and a second region;
a plurality of active fins in the first region and the second region, wherein each of the plurality of active fins protrudes from a substrate, and extends in a first direction;
a gate structure on the active fins in the first and second regions, the gate structure extending in a second direction perpendicular to the first direction to cross over the active fins;
a plurality of first insulation structures extending in the second direction in parallel with the gate structure formed in the first region, the first insulation structures being spaced apart from both sides in the first direction of the gate structure formed in the first region, respectively; and
a plurality of second insulation structures extending in the second direction in parallel with the gate structure formed in the second region, the second insulation structures being spaced apart from both sides in the first direction of the gate structure formed in the second region, respectively,
wherein an end portion in the second direction of one of the first insulation structures contacts an end portion in the second direction of one of the second insulation structures, and the first and second insulation structures are merged into one merged insulation structure crossing over both of the first and second regions,
wherein one gate structure is formed between two merged insulation structures, and
wherein a lower surface of the merged insulation structure is lower than upper surfaces of the active fins, and upper surfaces of the merged insulation structure and the gate structure are coplanar with each other.

16. The semiconductor memory device of claim 15, further comprising:
a first impurity region doped with p-type impurities between the gate structure and each of the first insulation structures;
a first contact plug contacting the first impurity region;
a second impurity region doped with n-type impurities between the gate structure and each of the second insulation structures; and
a second contact plug contacting the second impurity region.

17. The semiconductor memory device of claim 16, wherein upper surfaces of the first and second contact plugs are coplanar with the upper surfaces of the first and second insulation structures and the gate structure.

18. The semiconductor memory device of claim 16,
wherein each of the active fins includes a first recess between each of first insulation structures and the gate structure, and a first epitaxial pattern serving as the first impurity region is formed in the first recess, and
wherein each of the active fins includes a second recess between each of second insulation structures and the gate structure, and a second epitaxial pattern serving as the second impurity region is formed in the second recess.

19. The semiconductor memory device of claim 15,
wherein the gate structure includes a gate insulation pattern, a conductive pattern, an electrode pattern and a hard mask sequentially stacked, and
wherein the conductive pattern includes a metal for adjusting a threshold voltage.

20. The semiconductor memory device of claim 15, further comprising:
first spacers including a first material on sidewalls of the gate structure; and
second spacers including a second material substantially the same as the first material on sidewalls of the first insulation structures.
